(19) United States
(12) Patent Application Publication
(10) Pub. No.: US 2026/0068656 A1
(43) Pub. Date: Mar. 5, 2026

(54) SEMICONDUCTOR DEVICE

(71) Applicant: Mitsubishi Electric Corporation, Tokyo (JP)

(72) Inventors: Hiroya HAMADA, Tokyo (JP); Kenji HARADA, Tokyo (JP); Seiya NAKANO, Tokyo (JP); Kakeru OTSUKA, Tokyo (JP); Shinya SONEDA, Tokyo (JP)

(73) Assignee: Mitsubishi Electric Corporation, Tokyo (JP)

(21) Appl. No.: 19/218,169

(22) Filed: May 23, 2025

(30) Foreign Application Priority Data
Aug. 30, 2024 (JP) 2024-148661

(51) Int. Cl. H01L 23/34; H01L 23/528

(52) U.S. Cl. CPC H01L 23/34

(57) ABSTRACT

A semiconductor device includes an emitter electrode, a temperature sensing unit provided adjacent to the emitter electrode, a sense wiring, and a first wire bond portion provided adjacent to a connection portion between the emitter electrode and the sense wiring. The sense wiring includes a first sense wiring portion, a second sense wiring portion, and a bent portion. A distance from the connection portion to the first wire bond portion is shorter than a distance from the bent portion to the connection portion.

### BACKGROUND

### Technical Field

The present disclosure relates to a semiconductor device.

### Description of the Background Art

There has been proposed a configuration in which a wiring drawn out from either an anode or a cathode of a temperature sensing unit provided on a semiconductor chip is connected to a main current electrode such as an emitter electrode of a semiconductor element (for example, PCT International Publication No. 2015/029159). According to such a configuration, since a part of the main current electrode can be used as an electrode pad of the temperature sensing unit, an area required for the electrode pad of the temperature sensing unit can be reduced.

In the above configuration, a distance between a connection portion between the wiring drawn from the temperature sensing unit and the main current electrode, and a wire bonding portion to be wire-bonded to a wire for reading potential of the temperature sensing unit in the main current electrode may become long. In a case where this distance becomes long, potential of the temperature sensing unit read by the wire is strongly affected by main current flowing through the main current electrode, and thus there has been a problem that potential of the temperature sensing unit cannot be measured (cannot be read) correctly.

### SUMMARY

The present disclosure has been made in view of the above problem, and an object of the present disclosure is to provide a technique capable of correctly measuring potential of a temperature sensing unit.

A semiconductor device according to the present disclosure includes a semiconductor substrate having a first main surface, an emitter electrode selectively provided on the first main surface, a temperature sensing unit provided on the first main surface and adjacent to the emitter electrode further on the inner side than a terminal end of the semiconductor substrate in plan view, a sense wiring having one end connected to the temperature sensing unit and another end connected to the emitter electrode at the terminal end of the semiconductor substrate, the sense wiring being provided along the emitter electrode, and a first wire bond portion provided on the emitter electrode and adjacent to a connection portion between the emitter electrode and the sense wiring, in which the sense wiring includes a first sense wiring portion extending in a first direction from the inner side of the semiconductor substrate to the terminal end in plan view, a second sense wiring portion extending at the terminal end from the first sense wiring portion to the connection portion along a second direction different from the first direction of the first sense wiring portion, and a bent portion between the first sense wiring portion and the second sense wiring portion, and a distance from the connection portion to the first wire bond portion is shorter than a distance from the bent portion to the connection portion.

It is possible to correctly measure potential of the temperature sensing unit.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view illustrating a configuration of a semiconductor device according to a first preferred embodiment;

FIG. 2 is a plan view illustrating another configuration of the semiconductor device according to the first preferred embodiment;

FIG. 3 is a partially enlarged plan view illustrating a configuration of an IGBT region of the semiconductor device according to the first preferred embodiment;

FIGS. 4 and 5 cross-sectional views each illustrating a configuration of the IGBT region of the semiconductor device according to the first preferred embodiment;

FIG. 6 is a partially enlarged plan view illustrating a configuration of a diode region of the semiconductor device according to the first preferred embodiment;

FIGS. 7 and 8 are cross-sectional views each illustrating a configuration of the diode region of the semiconductor device according to the first preferred embodiment;

FIG. 9 is a cross-sectional view illustrating a configuration of a boundary region between the IGBT region and the diode region of the semiconductor device according to the first preferred embodiment;

FIGS. 10 and 11 are cross-sectional views each illustrating a configuration of a termination region of the semiconductor device according to the first preferred embodiment;

FIGS. 12A to 17B are cross-sectional views each illustrating a method of manufacturing the semiconductor device according to the first preferred embodiment;

FIG. 18 is a cross-sectional view illustrating a configuration of the semiconductor device according to the first preferred embodiment;

FIG. 19 is a plan view schematically illustrating a configuration of the semiconductor device according to the first preferred embodiment;

FIG. 20 is a plan view schematically illustrating a configuration of a related device;

FIG. 21 is a plan view schematically illustrating a configuration of the semiconductor device according to the first preferred embodiment;

FIG. 22 is a plan view schematically illustrating a configuration of the semiconductor device according to a second preferred embodiment;

FIG. 23 is an enlarged plan view schematically illustrating a configuration of the semiconductor device according to a third preferred embodiment;

FIG. 24 is an enlarged plan view schematically illustrating a configuration of the semiconductor device according to a fourth preferred embodiment;

FIG. 25 is an enlarged plan view schematically illustrating a configuration of the semiconductor device according to a fifth preferred embodiment;

FIG. 26 is a plan view schematically illustrating a configuration of the semiconductor device according to a sixth preferred embodiment;

FIG. 27 is a plan view schematically illustrating a configuration of the semiconductor device according to a seventh preferred embodiment;

FIG. 28 is a plan view schematically illustrating a configuration of the semiconductor device according to an eighth preferred embodiment; and

FIG. 29 is a plan view schematically illustrating a configuration of the semiconductor device according to a ninth preferred embodiment.

### DESCRIPTION OF THE PREFERRED EMBODIMENTS

### First Preferred Embodiment

In description below, n and p represent a conductivity type of a semiconductor, and in the present disclosure, a first conductivity type is described as an n type and a second conductivity type is described as a p type, but the first conductivity type may be described as a p type and the second conductivity type may be described as an n type. Further, n-indicates that impurity concentration is lower than that of n, and n⁺ indicates that impurity concentration is higher than that of n. Similarly, p⁻ indicates that impurity concentration is lower than that of ρ, and p⁺ indicates that impurity concentration is higher than that of p.

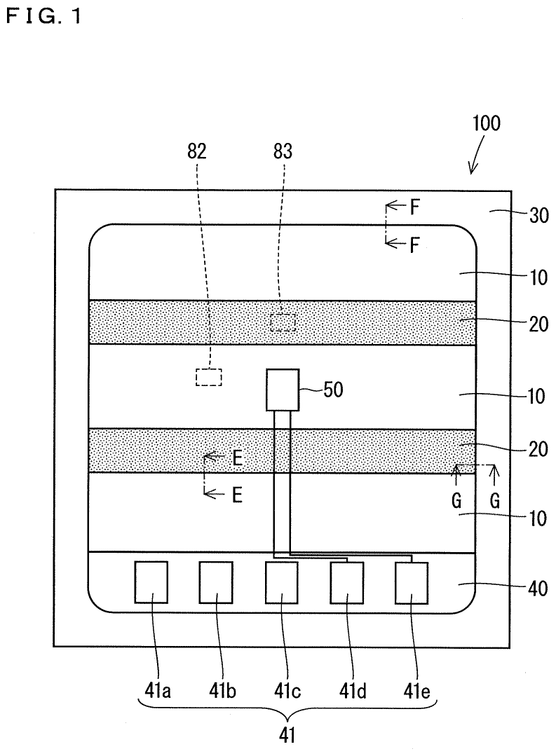

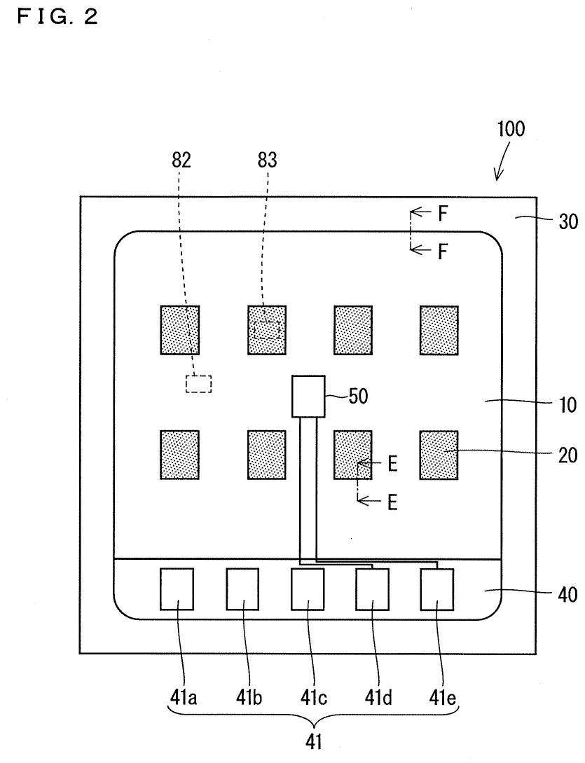

FIG. 1 is a plan view illustrating a semiconductor device including a reverse conducting IGBT (RC-IGBT). Further, FIG. 2 is a plan view illustrating another configuration of the semiconductor device including an RC-IGBT according to a first preferred embodiment. A semiconductor device 100 illustrated in FIG. 1 is provided with an IGBT region 10 and a diode region 20 arranged in a stripe shape, and may be simply referred to as a “stripe type”. The semiconductor device 100 illustrated in FIG. 2 is provided with a plurality of the diode regions 20 in a longitudinal direction and a lateral direction, and the IGBT region 10 is provided around the diode region 20, and may be simply referred to as an “island type”.

### <Overall Planar Structure of Stripe Type>

In FIG. 1, the semiconductor device 100 includes the IGBT region 10 and the diode region 20 in one semiconductor device. The IGBT region 10 and the diode region 20 extend from one end side to another end side of the semiconductor device 100, and are alternately provided in a stripe shape in a direction orthogonal to an extending direction of the IGBT region 10 and the diode region 20. FIG. 1 illustrates a configuration in which three of the IGBT regions 10 and two of the diode regions 20 are illustrated, and all the diode regions 20 are sandwiched between the IGBT regions 10. However, the numbers of the IGBT regions 10 and the diode regions 20 are not limited to these, and the number of the IGBT regions 10 may be three or more or three or less, and the number of the diode regions 20 may be two or more or two or less.

Further, the configuration may be such that only the IGBT region 10 is provided without provision of the diode region 20 at all. Further, instead of an IGBT, a metal oxide semiconductor field effect transistor (MOSFET) in which a region functioning as a collector of the IGBT region 10 is eliminated may be provided. Further, a diode of the diode region 20 may be a free wheeling diode (FWD), a Schottky barrier diode (SBD), or a PN junction diode (PND). Further, the configuration may be such that the IGBT region 10 and the diode region 20 in FIG. 1 are interchanged in location, or all the IGBT regions 10 are sandwiched between the diode regions 20. Further, the configuration may be such that the IGBT region 10 and the diode region 20 are provided adjacent to each other one by one.

As illustrated in FIG. 1, a pad region 40 is provided adjacent to the IGBT region 10 on the lower side in the diagram. The pad region 40 is a region where an electrode pad 41 for controlling the semiconductor device 100 is provided. In description below, the IGBT region 10 and the diode region 20 may be collectively referred to as a cell region. A termination region 30 is provided around a region that combines the cell region and the pad region 40 in order to maintain withstand voltage of the semiconductor device 100. A well-known withstand voltage holding structure may be appropriately provided in the termination region 30. In the withstand voltage holding structure, for example, a field limiting ring (FLR) surrounding a cell region with a p-type termination well layer of a p-type semiconductor or a variation of lateral doping (VLD) surrounding a cell region with a p-type well layer having concentration gradient may be provided on the first main surface side which is the front surface side of the semiconductor device 100. Note that the number of ring-shaped p-type termination well layers used for an FLR and concentration distribution used for a VLD only need to be appropriately selected according to a withstand voltage design of the semiconductor device 100. Further, a p-type termination well layer may be provided over substantially the entire pad region 40, and an IGBT cell or a diode cell may be provided in the pad region 40.

The electrode pad 41 includes, for example, at least one of a current sense pad 41a, a Kelvin emitter pad 41b, a gate pad 41c, and temperature sensing diode pads 41d and 41e. Note that in the present description, for example, at least one of A, B, C, . . . , and Z means any one of all combinations obtained by extracting one or more types from groups of A, B, C, . . . , and Z.

The current sense pad 41a is an electrode pad for detecting current flowing through a cell region of the semiconductor device 100. When current flows through a cell region of the semiconductor device 100, the current sense pad 41a is electrically connected to a part of the cell region such that current of a fraction ranging from several tenths to several ten-thousandths of current flowing through the entire cell region flows through an IGBT cell or a diode cell in a part of the cell region.

The Kelvin emitter pad 41b and the gate pad 41c are electrode pads to which gate drive voltage for controlling on and off of the semiconductor device 100 is applied. The Kelvin emitter pad 41b is electrically connected to a p-type base layer of an IGBT cell. The gate pad 41c is electrically connected to a gate trench electrode of an IGBT cell. The Kelvin emitter pad 41b and a p-type base layer may also be electrically connected via a p⁺-type contact layer. The temperature sensing diode pads 41d and 41e are electrode pads electrically connected to an anode and a cathode of a temperature sensing diode which is a temperature sensing unit 50 provided in the semiconductor device 100. Voltage between an anode and a cathode of a temperature sensing diode (not illustrated) provided in a cell region is measured via the temperature sensing diode pads 41d and 41e, and temperature of the semiconductor device 100 is measured based on the voltage.

### <Overall Planar Structure of Island Type>

In FIG. 2, the semiconductor device 100 includes the IGBT region 10 and the diode region 20 in one semiconductor device. A plurality of the diode regions 20 are arranged side by side in a longitudinal direction and a lateral direction in the semiconductor device 100, and the diode region 20 is surrounded by the IGBT region 10. That is, a plurality of the diode regions 20 are provided in an island shape in the IGBT region 10. FIG. 2 illustrates a configuration in which the diode regions 20 are provided in a matrix of four columns in a horizontal direction in the diagram and two rows in a vertical direction in the diagram. However, the number and arrangement of the diode regions 20 are not limited to these, and the configuration only needs to be that in which one or a plurality of the diode regions 20 are interspersed in the IGBT region 10, and the periphery of each of the diode regions 20 is surrounded by the IGBT region 10.

As illustrated in FIG. 2, the pad region 40 is provided adjacent to the lower side in the diagram of the IGBT region 10. The pad region 40 is a region where an electrode pad 41 for controlling the semiconductor device 100 is provided. Also in this description, the IGBT region 10 and the diode region 20 are collectively referred to as a cell region. A termination region 30 is provided around a region that combines the cell region and the pad region 40 in order to maintain withstand voltage of the semiconductor device 100. A well-known withstand voltage holding structure may be appropriately provided in the termination region 30. In the withstand voltage holding structure, for example, on the first main surface side which is the front surface side of the semiconductor device 100, an FLR surrounding a region combining the cell region and the pad region 40 with a p-type termination well layer of a p-type semiconductor or a VLD surrounding a cell region with a p-type well layer with concentration gradient may be provided. Note that the number of ring-shaped p-type termination well layers used for an FLR and concentration distribution used for a VLD only need to be appropriately selected according to a withstand voltage design of the semiconductor device 100. Further, a p-type termination well layer may be provided over substantially the entire pad region 40, and an IGBT cell or a diode cell may be provided in the pad region 40.

The electrode pad 41 includes, for example, at least one of a current sense pad 41a, a Kelvin emitter pad 41b, a gate pad 41c, and temperature sensing diode pads 41d and 41e.

The current sense pad 41a is an electrode pad for detecting current flowing through a cell region of the semiconductor device 100. When current flows through a cell region of the semiconductor device 100, the current sense pad 41a is electrically connected to a part of the cell region such that current of a fraction ranging from several tenths to several ten-thousandths of current flowing through the entire cell region flows through an IGBT cell or a diode cell in a part of the cell region.

The Kelvin emitter pad 41b and the gate pad 41c are electrode pads to which gate drive voltage for controlling on and off of the semiconductor device 100 is applied. The Kelvin emitter pad 41b is electrically connected to a p-type base layer and an n⁺-type source layer of an IGBT cell. The gate pad 41c is electrically connected to a gate trench electrode of an IGBT cell. The Kelvin emitter pad 41b and a p-type base layer may also be electrically connected via a p⁺-type contact layer. The temperature sensing diode pads 41d and 41e are electrode pads electrically connected to an anode and a cathode of a temperature sensing diode which is a temperature sensing unit 50 provided in the semiconductor device 100. Voltage between an anode and a cathode of a temperature sensing diode (not illustrated) provided in a cell region is measured via the temperature sensing diode pads 41d and 41e, and temperature of the semiconductor device 100 is measured based on the voltage.

### <IGBT Region 10>

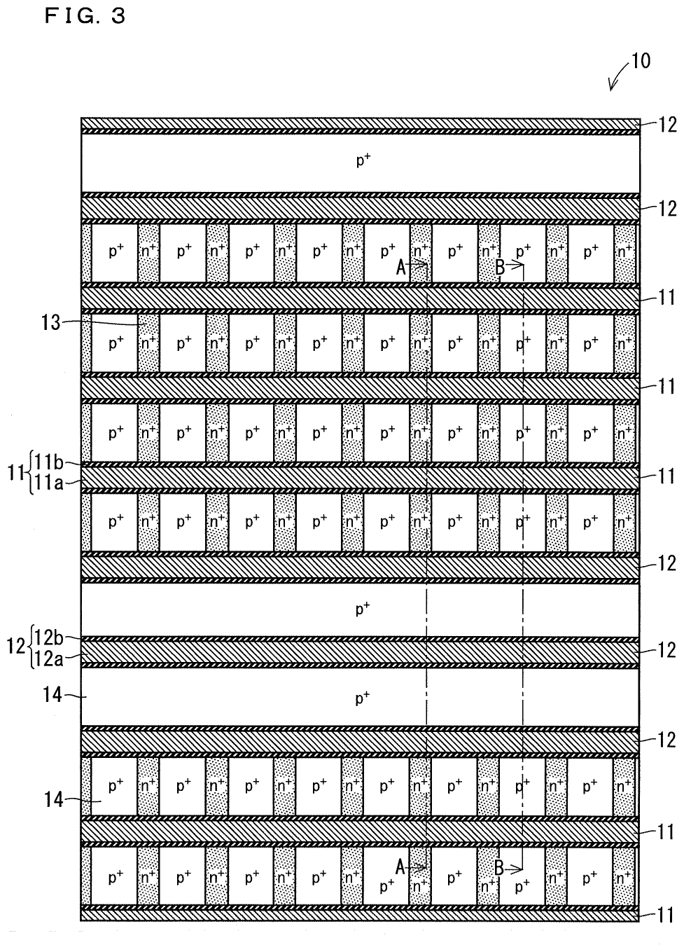

FIG. 3 is a partially enlarged plan view illustrating a configuration of the IGBT region 10 of a semiconductor device that is an RC-IGBT. Specifically, FIG. 3 is an enlarged view of a region surrounded by a broken line 82 in the semiconductor device 100 illustrated in FIGS. 1 and 2.

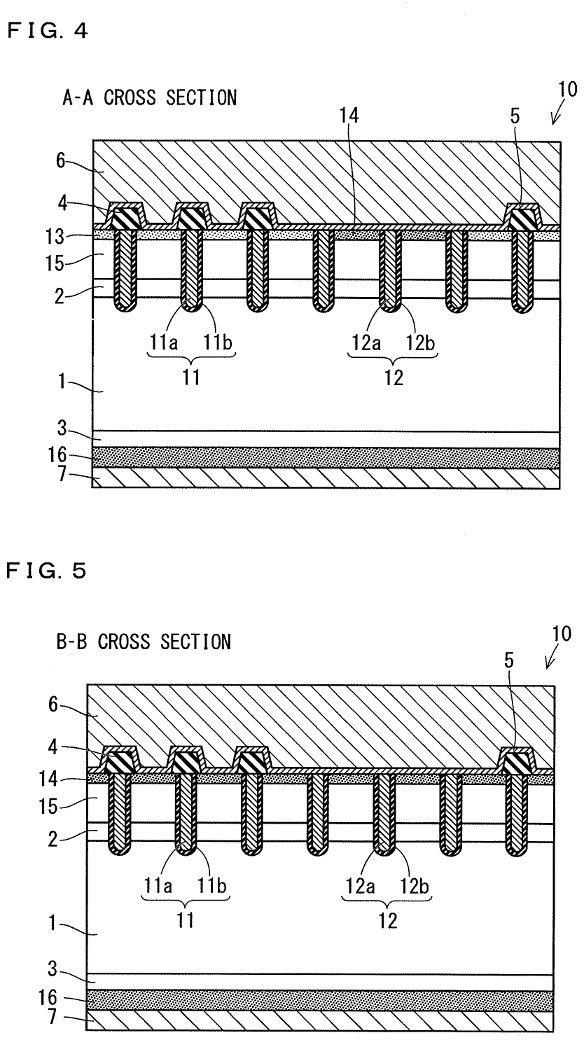

Further, FIGS. 4 and 5 are cross-sectional views illustrating a configuration of the IGBT region 10 of a semiconductor device that is an RC-IGBT. Specifically, FIG. 4 is a cross-sectional view taken along an alternate long and short dash line A-A of the semiconductor device 100 illustrated in FIG. 3, and FIG. 5 is a cross-sectional view taken along an alternate long and short dash line B-B of the semiconductor device 100 illustrated in FIG. 3.

As illustrated in FIG. 3, an active trench gate 11 and a dummy trench gate 12 are provided in a stripe shape in the IGBT region 10. In the semiconductor device 100 of FIG. 1, the active trench gate 11 and the dummy trench gate 12 extend in a longitudinal direction of the IGBT region 10, and the longitudinal direction of the IGBT region 10 corresponds to a longitudinal direction of the active trench gate 11 and the dummy trench gate 12. On the other hand, in the semiconductor device 100 of FIG. 2, a longitudinal direction and a lateral direction are not particularly distinguished in the IGBT region 10, and a left-right direction in the diagram may correspond to a longitudinal direction of the active trench gate 11 and the dummy trench gate 12, and a vertical direction in the diagram may correspond to a longitudinal direction of the active trench gate 11 and the dummy trench gate 12.

The active trench gate 11 is configured such that a gate trench electrode 11a is provided in a trench of a semiconductor substrate with a gate trench insulating film 11b interposed between them. The dummy trench gate 12 is configured such that a dummy trench electrode 12a is provided in a trench of a semiconductor substrate with a dummy trench insulating film 12b interposed between them. The gate trench electrode 11a of the active trench gate 11 is electrically connected to the gate pad 41c of FIGS. 1 and 2. The dummy trench electrode 12a of the dummy trench gate 12 is electrically connected to an emitter electrode provided on the first main surface of the semiconductor device 100.

As illustrated in FIG. 3, an n⁺-type source layer 13 is provided in contact with the gate trench insulating film 11b on both sides in a width direction of the active trench gate 11. The n⁺-type source layer 13 is also called an n⁺-type emitter layer depending on a semiconductor device. The n⁺-type source layer 13 is a semiconductor layer containing, for example, arsenic or phosphorus as an n-type impurity, and concentration of the n-type impurity is 1.0E+17/cm³ to 1.0E+20/cm³. Further, the n⁺-type source layer 13 is provided alternately with a p⁺-type contact layer 14 along an extending direction of the active trench gate 11. Further, the p⁺-type contact layer 14 is provided between two of the dummy trench gates 12 adjacent to each other so as to be in contact with the dummy trench insulating film 12b. The p⁺-type contact layer 14 is a semiconductor layer containing, for example, boron or aluminum as a p-type impurity, and concentration of the p-type impurity is, for example, 1.0E+15/cm³ to 1.0E+20/cm³.

As illustrated in FIG. 3, in the IGBT region 10 of the semiconductor device 100, three of the dummy trench gates 12 are arranged next to arrangement of three of the active trench gates 11. Then, three of the active trench gates 11 different from those described above are arranged next to three of the dummy trench gates 12 described above. The IGBT region 10 has a configuration in which a set of the active trench gates 11 and a set of the dummy trench gates 12 are alternately arranged as described above. In FIG. 3, the number of the active trench gates 11 included in one set of the active trench gates 11 is three, but may be any number that is one or more. Further, the number of the dummy trench gates 12 included in one set of the dummy trench gates 12 may be one or more, and the number of the dummy trench gates 12 may be zero. That is, all trench gates provided in the IGBT region 10 may be the active trench gates 11.

FIG. 4 is a cross-sectional view of the semiconductor device 100 taken along the alternate long and short dash line A-A in FIG. 3, and is a cross-sectional view of the IGBT region 10. The semiconductor device 100 includes an n⁻-type drift layer 1 including a semiconductor substrate. The n⁻-type drift layer 1 is a semiconductor layer containing, for example, arsenic or phosphorus as an n-type impurity, and concentration of the n-type impurity is, for example, 1.0E+12/cm³ to 1.0E+15/cm³. Note that concentration of the n-type impurity in the n⁺-type source layer 13 described above is higher than concentration of the n-type impurity in the n-type drift layer 1.

In FIG. 4, a range of the semiconductor substrate is a range from the n⁺-type source layer 13 and the p⁺-type contact layer 14 to a p-type collector layer 16. The p-type collector layer 16 is also called a p-type drain layer depending on a semiconductor device. In FIG. 4, an upper end in the diagram of the n⁺-type source layer 13 and the p⁺-type contact layer 14 is referred to as a first main surface of the semiconductor substrate, and a lower end in the diagram of the p-type collector layer 16 is referred to as a second main surface of the semiconductor substrate. The first main surface of the semiconductor substrate is a main surface on the front surface side of the semiconductor device 100, and the second main surface of the semiconductor substrate is a main surface on the back surface side of the semiconductor device 100. The semiconductor device 100 includes the n-type drift layer 1 between the first main surface and the second main surface on the opposite side to the first main surface in the IGBT region 10 that is a cell region. Note that the semiconductor substrate may include, for example, at least one of a wafer and an epitaxial growth layer. Further, the semiconductor substrate may include a wide band gap semiconductor (silicon carbide (SiC), gallium nitride (GaN), and diamond) that enables stable operation at high temperature.

As illustrated in FIG. 4, in the IGBT region 10, an n-type carrier storage layer 2 having higher concentration of an n-type impurity than the n⁻-type drift layer 1 is provided on the first main surface side of the n⁻-type drift layer 1. The n-type carrier storage layer 2 is a semiconductor layer containing, for example, arsenic or phosphorus as an n-type impurity, and concentration of the n-type impurity is, for example, 1.0E+13/cm³ to 1.0E +17/cm³. Note that the semiconductor device 100 may have a configuration in which the n-type carrier storage layer 2 is not provided and the n-type drift layer 1 is provided also in a region of the n-type carrier storage layer 2 illustrated in FIG. 4. By providing the n-type carrier storage layer 2, an energization loss when current flows in the IGBT region 10 can be reduced. The n-type carrier storage layer 2 and the n⁻-type drift layer 1 may be collectively referred to as a drift layer.

The n-type carrier storage layer 2 is formed by ion-implanting an n-type impurity into a semiconductor substrate constituting the n⁻-type drift layer 1 and then diffusing the implanted n-type impurity into the semiconductor substrate as the n⁻-type drift layer 1 by annealing.

A p-type base layer 15 is provided on the first main surface side of the n-type carrier storage layer 2. The p-type base layer 15 is a semiconductor layer containing, for example, boron or aluminum as a p-type impurity, and concentration of the p-type impurity is, for example, 1.0E+12/cm³ to 1.0E+19/cm³. The p-type base layer 15 is in contact with the gate trench insulating film 11b of the active trench gate 11. In the example of FIG. 4, the p-type base layer 15 is also in contact with the dummy trench insulating film 12b of the dummy trench gate 12.

The n⁺-type source layer 13 in contact with the gate trench insulating film 11b of the active trench gate 11 is provided in a partial region on the first main surface side of the p-type base layer 15, and the p⁺-type contact layer 14 is selectively provided in the remaining region on the first main surface side of the p-type base layer 15. The n⁺-type source layer 13 and the p⁺-type contact layer 14 constitute the first main surface of the semiconductor substrate. Note that the p⁺-type contact layer 14 is a region having higher p-type impurity concentration than the p-type base layer 15. In a case where the p⁺-type contact layer 14 and the p-type base layer 15 need to be distinguished from each other, they may be referred to individually, or in a case where the p⁺-type contact layer 14 and the p-type base layer 15 do not need to be distinguished from each other, they may be collectively referred to as a p-type base layer.

Further, on the second main surface side of the n⁻-type drift layer 1 of the semiconductor device 100, an n-type buffer layer 3 having higher concentration of an n-type impurity than the n-type drift layer 1 is provided. The n-type buffer layer 3 is provided to prevent punch-through of a depletion layer extending from the p-type base layer 15 to the second main surface side when the semiconductor device 100 is in an off state. The n-type buffer layer 3 may be formed by, for example, injecting phosphorus (P) or a proton (H⁺), or may be formed by injecting both phosphorus (P) and a proton (H⁺). Concentration of an n-type impurity in the n-type buffer layer 3 is, for example, 1.0E+12/cm³ to 1.0E+18/cm³. Note that the semiconductor device 100 may have a configuration in which the n-type buffer layer 3 is not provided and the n⁻-type drift layer 1 is also provided in a region of the n-type buffer layer 3 illustrated in FIG. 4. The n-type buffer layer 3 and the n-type drift layer 1 may be collectively referred to as a drift layer.

On the second main surface side of the n-type buffer layer 3 of the semiconductor device 100, the p-type collector layer 16 is provided. That is, the p-type collector layer 16 is provided between the n⁻-type drift layer 1 and the second main surface. The p-type collector layer 16 is a semiconductor layer containing, for example, boron or aluminum as a p-type impurity, and concentration of the p-type impurity is, for example, 1.0E+16/cm³ to 1.0E+20/cm³. The p-type collector layer 16 constitutes the second main surface of the semiconductor substrate. The p-type collector layer 16 may be provided as a p-type termination collector layer 16a described later not only in the IGBT region 10 but also in the termination region 30. Further, the p-type collector layer 16 may be provided so as to partially protrude from the IGBT region 10 into the diode region 20.

As illustrated in FIG. 4, a trench that penetrates the p-type base layer 15 from the first main surface of the semiconductor substrate and reaches the n⁻-type drift layer 1 is provided in the IGBT region 10 of the semiconductor device 100. The gate trench electrode 11a is provided in some trenches with the gate trench insulating film 11b interposed between them to constitute the active trench gate 11. The gate trench electrode 11a faces the n⁻-type drift layer 1 with the gate trench insulating film 11b interposed between them.

Further, the dummy trench electrode 12a is provided in some trenches with the dummy trench insulating film 12b interposed between them to constitute the dummy trench gate 12. The dummy trench electrode 12a faces the n⁻-type drift layer 1 with the dummy trench insulating film 12b interposed between them.

The gate trench insulating film 11b of the active trench gate 11 is in contact with the p-type base layer 15 and the n⁺-type source layer 13. When gate drive voltage is applied to the gate trench electrode 11a, a channel is formed in the p-type base layer 15 in contact with the gate trench insulating film 11b of the active trench gate 11.

As illustrated in FIG. 4, an interlayer insulating film 4 is provided on the gate trench electrode 11a of the active trench gate 11. Barrier metal 5 is formed on a region where the interlayer insulating film 4 is not provided on the first main surface of the semiconductor substrate and on the interlayer insulating film 4. The barrier metal 5 may be, for example, a conductor containing titanium (Ti), and may be, specifically, titanium nitride or TiSi obtained by alloying titanium and silicon (Si). As illustrated in FIG. 4, the barrier metal 5 is in ohmic contact with the n⁺-type source layer 13, the p⁺-type contact layer 14, and the dummy trench electrode 12a, and is electrically connected to the n⁺-type source layer 13, the p⁺-type contact layer 14, and the dummy trench electrode 12a. On the other hand, the barrier metal 5 is electrically insulated from the gate trench electrode 11a by the interlayer insulating film 4.

An emitter electrode 6 is provided on the barrier metal 5. The emitter electrode 6 may be formed of, for example, an aluminum alloy such as an aluminum silicon alloy (Al—Si-based alloy), or may be an electrode including a plurality of layers of metal films in which a plating film is formed on an electrode formed of an aluminum alloy by electroless plating or electrolytic plating. The plating film formed by electroless plating or electrolytic plating may be, for example, a nickel (Ni) plating film. In a case where there is a fine region between adjacent ones of the interlayer insulating films 4 or the like, the region being where favorable embedding cannot be obtained by the emitter electrode 6, a tungsten film having better embeddability than the emitter electrode 6 may be arranged in the fine region, and the emitter electrode 6 may be provided on the tungsten film. Note that the emitter electrode 6 may be provided on the n⁺-type source layer 13, the p⁺-type contact layer 14, and the dummy trench electrode 12a without provision of the barrier metal 5. Further, the barrier metal 5 may be provided only on an n-type semiconductor layer such as the n⁺-type source layer 13. The barrier metal 5 and the emitter electrode 6 may be collectively referred to as an emitter electrode.

Note that although FIG. 4 illustrates a configuration in which the interlayer insulating film 4 is not provided on the dummy trench electrode 12a of the dummy trench gate 12, the interlayer insulating film 4 may be provided on the dummy trench electrode 12a of the dummy trench gate 12 in a cross-sectional portion of FIG. 4. In a case where the interlayer insulating film 4 is provided on the dummy trench electrode 12a of the dummy trench gate 12 in the cross-sectional portion of FIG. 4, the emitter electrode 6 and the dummy trench electrode 12a may be electrically connected in another cross-sectional portion.

A collector electrode 7 is provided on the second main surface side of the p-type collector layer 16. Similarly to the emitter electrode 6, the collector electrode 7 may include an aluminum alloy, or a plurality of layers of an aluminum alloy and a plating film. The collector electrode 7 may have a configuration different from that of the emitter electrode 6. The collector electrode 7 is in ohmic contact with the p-type collector layer 16 and is electrically connected to the p-type collector layer 16. Note that a MOSFET may be provided instead of an IGBT without provision of the p-type collector layer 16.

FIG. 5 is a cross-sectional view of the semiconductor device 100 taken along the alternate long and short dash line B-B in FIG. 3, and is a cross-sectional view of the IGBT region 10. Unlike the cross-sectional portion taken along the alternate long and short dash line A-A illustrated in FIG. 4, in a cross-sectional portion taken along the alternate long and short dash line B-B in FIG. 5, there is none of the n⁺-type source layer 13 that is in contact with the active trench gate 11 and provided on the first main surface side of the semiconductor substrate. That is, the n⁺-type source layer 13 illustrated in FIG. 3 is selectively provided on the first main surface side of a p-type base layer. Note that the p-type base layer referred to here may include the p-type base layer 15 and the p⁺-type contact layer 14.

### <Diode Region 20>

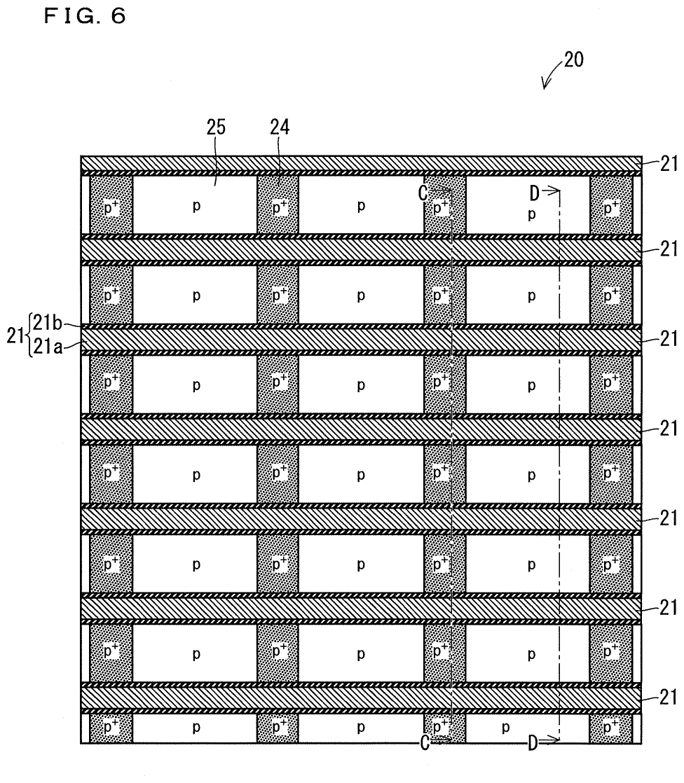

FIG. 6 is a partially enlarged plan view illustrating a configuration of the diode region 20 of the semiconductor device which is an RC-IGBT. Specifically, FIG. 6 is an enlarged view of a region surrounded by a broken line 83 in the semiconductor device 100 illustrated in FIGS. 1 and 2.

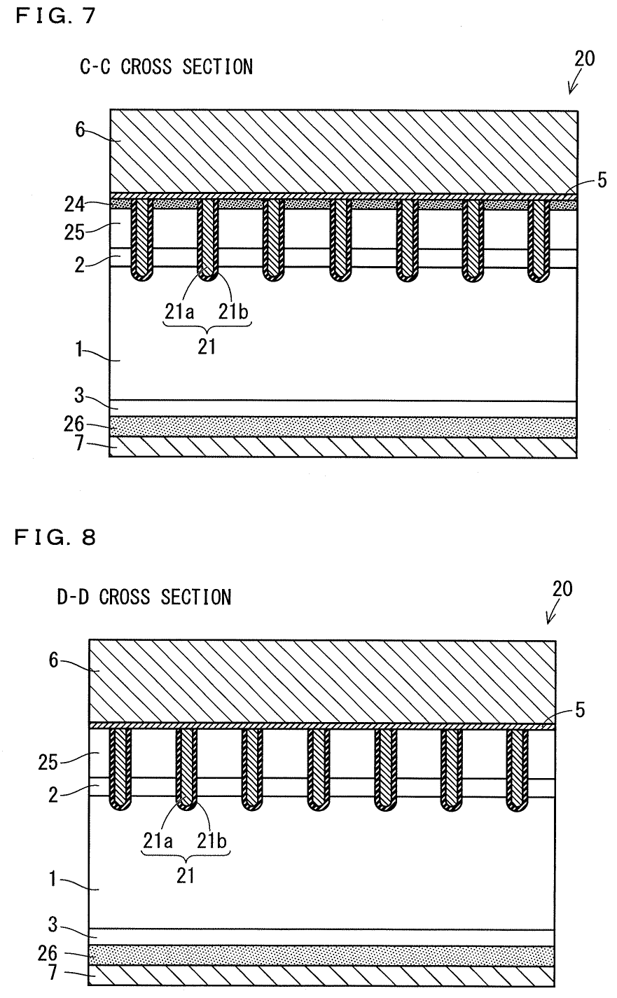

Further, FIGS. 7 and 8 are cross-sectional views illustrating a configuration of the diode region 20 of the semiconductor device which is an RC-IGBT. Specifically, FIG. 7 is a cross-sectional view taken along an alternate long and short dash line C-C of the semiconductor device 100 illustrated in FIG. 6, and FIG. 8 is a cross-sectional view taken along an alternate long and short dash line D-D of the semiconductor device 100 illustrated in FIG. 6.

A diode trench gate 21 extends along the first main surface of the semiconductor device 100 from one end side of the diode region 20 of a cell region, toward facing another end side. The diode trench gate 21 is constituted by provision of a diode trench electrode 21a in a trench of the diode region 20 with a diode trench insulating film 21b interposed between them. The diode trench electrode 21a faces the n⁻-type drift layer 1 with the diode trench insulating film 21b interposed between them.

A p⁺-type contact layer 24 and a p-type anode layer 25 having a p-type impurity concentration lower than that of the p⁺-type contact layer 24 are provided between two adjacent ones of the diode trench gates 21. The p⁺-type contact layer 24 is a semiconductor layer containing, for example, boron or aluminum as a p-type impurity, and concentration of the p-type impurity is, for example, 1.0E+15/cm³ to 1.0E+20/cm³. The p-type anode layer 25 is a semiconductor layer containing, for example, boron or aluminum as a p-type impurity, and concentration of the p-type impurity is, for example, 1.0E+12/cm³ to 1.0E +19/cm³. The p⁺-type contact layer 24 and the p-type anode layer 25 are alternately provided in a longitudinal direction of the diode trench gate 21.

FIG. 7 is a cross-sectional view of the semiconductor device 100 taken along the alternate long and short dash line C-C in FIG. 6, and is a cross-sectional view of the diode region 20. The semiconductor device 100 includes the n⁻-type drift layer 1 including a semiconductor substrate as in the IGBT region 10 also in the diode region 20. The n⁻-type drift layer 1 of the diode region 20 and the n-type drift layer 1 of the IGBT region 10 are continuously and integrally formed, and are formed of the same semiconductor substrate.

In FIG. 7, a range of the semiconductor substrate is a range from the p⁺-type contact layer 24 to an n⁺-type cathode layer 26. In FIG. 7, an upper end in the diagram of the p⁺-type contact layer 24 is referred to as a first main surface of the semiconductor substrate, and a lower end in the diagram of the n⁺-type cathode layer 26 is referred to as a second main surface of the semiconductor substrate. The first main surface of the diode region 20 and the first main surface of the IGBT region 10 are included in the same plane, and the second main surface of the diode region 20 and the second main surface of the IGBT region 10 are included in the same plane.

As illustrated in FIG. 7, also in the diode region 20, similarly to the IGBT region 10, the n-type carrier storage layer 2 is provided on the first main surface side of the n⁻-type drift layer 1, and the n-type buffer layer 3 is provided on the second main surface side of the n-type drift layer 1. The n-type carrier storage layer 2 and the n-type buffer layer 3 provided in the diode region 20 may have the same configuration as the n-type carrier storage layer 2 and the n-type buffer layer 3 provided in the IGBT region 10. Note that the n-type carrier storage layer 2 is not necessarily provided in the IGBT region 10 and the diode region 20, and, for example, the configuration may be such that the n-type carrier storage layer 2 is provided in the IGBT region 10 but not in the diode region 20. Further, similarly to the IGBT region 10, the n⁻-type drift layer 1, the n-type carrier storage layer 2, and the n-type buffer layer 3 may be collectively referred to as a drift layer.

The p-type anode layer 25 is provided on the first main surface side of the n-type carrier storage layer 2. The p-type anode layer 25 is provided between the n⁻-type drift layer 1 and the first main surface. Concentration of a p-type impurity of the p-type anode layer 25 may be set to be the same as concentration of a p-type impurity of the p-type base layer 15 of the IGBT region 10, and the p-type anode layer 25 and the p-type base layer 15 may be formed at the same time. Further, concentration of a p-type impurity of the p-type anode layer 25 may be set to be lower than concentration of a p-type impurity of the p-type base layer 15 of the IGBT region 10 so as to reduce an amount of holes injected into the diode region 20 during diode operation. By reducing an amount of holes injected during diode operation, a recovery loss during diode operation can be reduced.

The p⁺-type contact layer 24 is provided on the first main surface side of the p-type anode layer 25. Concentration of a p-type impurity of the p⁺-type contact layer 24 may be the same as or different from concentration of a p-type impurity of the p⁺-type contact layer 14 of the IGBT region 10. The p⁺-type contact layer 24 constitutes the first main surface of the semiconductor substrate. Note that the p⁺-type contact layer 24 is a region having higher concentration of a p-type impurity than the p-type anode layer 25, and in a case where it is necessary to distinguish the p⁺-type contact layer 24 and the p-type anode layer 25 from each other, the p⁺-type contact layer 24 and the p-type anode layer 25 may be referred to individually, and in a case where it is not necessary to distinguish the p⁺-type contact layer 24 and the p-type anode layer 25 from each other, the p⁺-type contact layer 24 and the p-type anode layer 25 may be collectively referred to as a p-type anode layer.

The n⁺-type cathode layer 26 is provided on the second main surface side of the n-type buffer layer 3 of the semiconductor device 100. That is, the n⁺-type cathode layer 26 is provided between the n⁻-type drift layer 1 and the second main surface. The n⁺-type cathode layer 26 is a semiconductor layer containing, for example, arsenic or phosphorus as an n-type impurity, and concentration of the n-type impurity is, for example, 1.0E+16/cm³ to 1.0E+21/cm³. The n⁺-type cathode layer 26 is provided in a part or the whole of the diode region 20. The n⁺-type cathode layer 26 constitutes the second main surface of the semiconductor substrate. Note that, although not illustrated, a p-type cathode layer that is a p-type semiconductor may be provided by further selectively implanting a p-type impurity into a part of a region where the n⁺-type cathode layer 26 is formed.

As illustrated in FIG. 7, a trench that penetrates the p-type anode layer 25 from the first main surface of the semiconductor substrate and reaches the n⁻-type drift layer 1 is provided in the diode region 20 of the semiconductor device 100. The diode trench electrode 21a is provided in a trench of the diode region 20 with the diode trench insulating film 21b interposed between them, so that the diode trench gate 21 is formed. The diode trench electrode 21a faces the n-type drift layer 1 with the diode trench insulating film 21b interposed between them.

As illustrated in FIG. 7, the barrier metal 5 is provided on the diode trench electrode 21a and the p⁺-type contact layer 24. The barrier metal 5 is in ohmic contact with the diode trench electrode 21a and the p⁺-type contact layer 24, and is electrically connected to the diode trench electrode 21a and the p⁺-type contact layer 24. The barrier metal 5 may have the same configuration as the barrier metal 5 in the IGBT region 10.

An emitter electrode 6 is provided on the barrier metal 5. The emitter electrode 6 provided in the diode region 20 is formed continuously with the emitter electrode 6 provided in the IGBT region 10. Note that, as in the case of the IGBT region 10, the diode trench electrode 21a and the p⁺-type contact layer 24 may be brought into ohmic contact with the emitter electrode 6 without provision of the barrier metal 5.

Note that although FIG. 7 illustrates the configuration in which the interlayer insulating film 4 as in FIG. 4 is not provided on the diode trench electrode 21a of the diode trench gate 21, the interlayer insulating film 4 may be provided on the diode trench electrode 21a in a cross-sectional portion of FIG. 7. In the cross-sectional portion of FIG. 7, in a case where the interlayer insulating film 4 is provided on the diode trench electrode 21a of the diode trench gate 21, the emitter electrode 6 and the diode trench electrode 21a only need to be electrically connected in another cross-sectional portion.

The collector electrode 7 is provided on the second main surface side of the n⁺-type cathode layer 26. Similarly to the emitter electrode 6, the collector electrode 7 of the diode region 20 is formed continuously with the collector electrode 7 provided in the IGBT region 10. The collector electrode 7 is in ohmic contact with the n⁺-type cathode layer 26 and is electrically connected to the n⁺-type cathode layer 26.

FIG. 8 is a cross-sectional view of the semiconductor device 100 taken along the alternate long and short dash line D-D in FIG. 6, and is a cross-sectional view of the diode region 20. Unlike the cross-sectional portion taken along the alternate long and short dash line C-C illustrated in FIG. 7, in a cross-sectional portion taken along the alternate long and short dash line D-D in FIG. 8, the p⁺-type contact layer 24 is not provided between the p-type anode layer 25 and the barrier metal 5, and the p-type anode layer 25 is the first main surface of the semiconductor substrate. That is, the p⁺-type contact layer 24 illustrated in FIG. 7 is selectively provided on the first main surface side of the p-type anode layer 25.

### <Configuration of Boundary Region Between IGBT Region 10 and Diode Region 20>

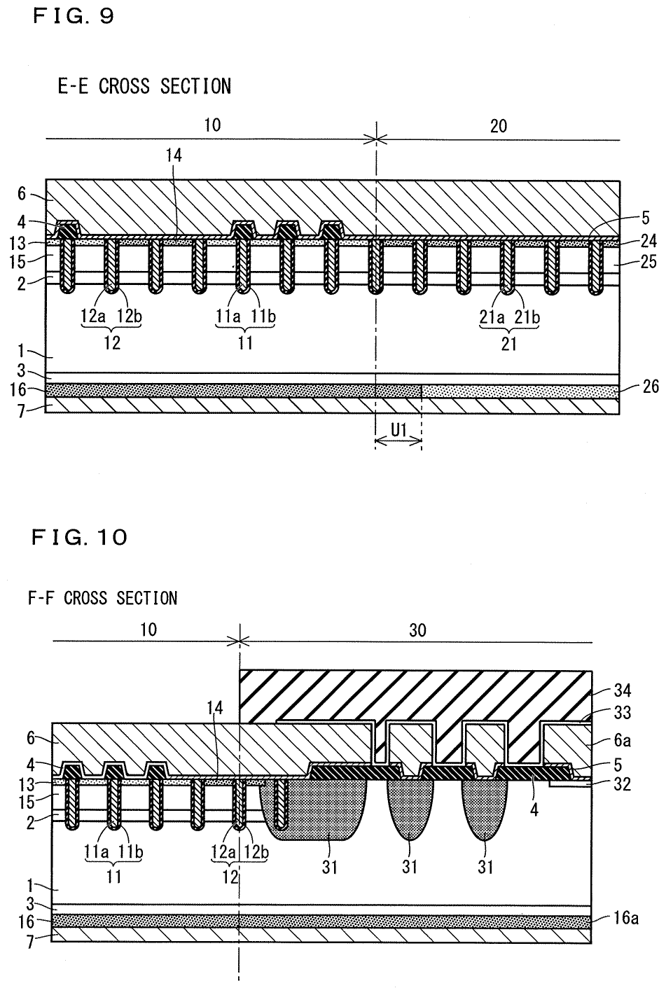

FIG. 9 is a cross-sectional view illustrating a configuration of a boundary region between the IGBT region 10 and the diode region 20 of the semiconductor device that is an RC-IGBT. Specifically, FIG. 9 is a cross-sectional view taken along an alternate long and short dash line E-E in the semiconductor device 100 illustrated in FIGS. 1 and 2.

As illustrated in FIG. 9, the p-type collector layer 16 provided on the second main surface side of the IGBT region 10 and the n⁺-type cathode layer 26 provided on the second main surface side of the diode region 20 are adjacent to each other in an in-plane direction of the semiconductor substrate. Then, the p-type collector layer 16 is provided so as to protrude toward the diode region 20 side by a distance U1 from a boundary between the IGBT region 10 and the diode region 20.

As described above, by providing the p-type collector layer 16 so as to protrude to the diode region 20, a distance between the n⁺-type cathode layer 26 of the diode region 20 and the active trench gate 11 can be increased. For this reason, even in a case where gate drive voltage is applied to the gate trench electrode 11a during freewheeling diode operation, current can be prevented from flowing from a channel formed adjacent to the active trench gate 11 of the IGBT region 10 to the n⁺-type cathode layer 26. The distance U1 may be, for example, 100 μm. Note that the distance U1 may be zero or a distance smaller than 100 μm depending on an application of the semiconductor device 100 which is an RC-IGBT.

### <Termination Region 30>

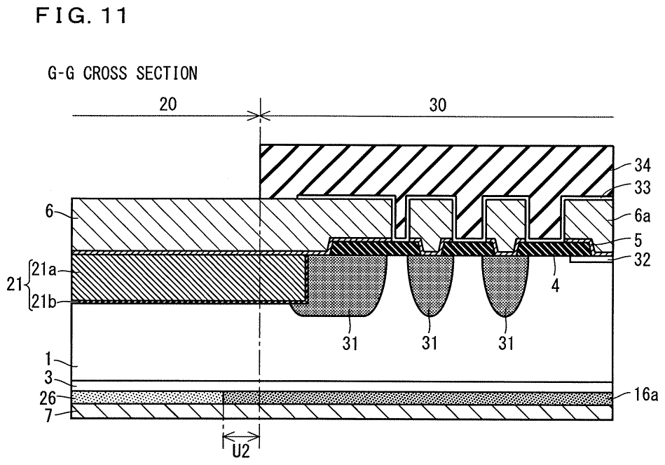

FIGS. 10 and 11 are cross-sectional views illustrating a configuration of the termination region 30 of the semiconductor device 100 that is an RC-IGBT. Specifically, FIG. 10 is a cross-sectional view taken along an alternate long and short dash line F-F illustrated in FIGS. 1 and 2, and is a cross-sectional view from the IGBT region 10 to the termination region 30. Further, FIG. 11 is a cross-sectional view taken along an alternate long and short dash line G-G illustrated in FIG. 1, and is a cross-sectional view from the diode region 20 to the termination region 30.

As illustrated in FIGS. 10 and 11, the termination region 30 of the semiconductor device 100 includes the n⁻-type drift layer 1 between the first main surface and the second main surface of the semiconductor substrate. The first main surface and the second main surface of the termination region 30 are included in the same plane as the first main surface and the second main surface of the IGBT region 10 and the diode region 20, respectively. Further, the n⁻-type drift layer 1 of the termination region 30 has the same configuration as the n⁻-type drift layer 1 of each of the IGBT region 10 and the diode region 20, and is continuously and integrally constituted.

A p-type termination well layer 31 is selectively provided on the first main surface side of the n⁻-type drift layer 1, that is, between the first main surface of the semiconductor substrate and the n⁻-type drift layer 1. The p-type termination well layer 31 is a semiconductor layer containing, for example, boron or aluminum as a p-type impurity, and concentration of the p-type impurity is, for example, 1.0E+14/cm³ to 1.0E+19/cm³. The p-type termination well layer 31 is provided to surround a cell region including the IGBT region 10 and the diode region 20. The p-type termination well layer 31 is provided in a plurality of ring shapes, and the number of the p-type termination well layers 31 to be provided is appropriately selected according to withstand voltage design of the semiconductor device 100. Further, an n⁺-type channel stopper layer 32 is provided further on the outer edge side of the p-type termination well layer 31, and the n⁺-type channel stopper layer 32 surrounds the p-type termination well layer 31 in plan view.

The p-type termination collector layer 16a is provided between the n-type drift layer 1 of the termination region 30 and the second main surface of the semiconductor substrate. The p-type termination collector layer 16a is continuously and integrally formed with the p-type collector layer 16 provided in the IGBT region 10 of a cell region. Therefore, the p-type collector layer 16 including the p-type termination collector layer 16a may be referred to as a p-type collector layer.

In the configuration in which the diode region 20 is provided adjacent to the termination region 30 as in the semiconductor device 100 illustrated in FIG. 1, as illustrated in FIG. 11, the p-type termination collector layer 16a is provided to have an end portion on the diode region 20 side protruding to the diode region 20 by a distance U2. According to such a configuration, since a distance between the n⁺-type cathode layer 26 of the diode region 20 and the p-type termination well layer 31 can be increased, it is possible to prevent the p-type termination well layer 31 from operating as an anode of a diode. The distance U2 may be, for example, 100 μm.

The collector electrode 7 is provided on the second main surface of the semiconductor substrate. The collector electrode 7 is integrally formed continuously from a cell region including the IGBT region 10 and the diode region 20 to the termination region 30.

On the other hand, the emitter electrode 6 continuous from a cell region and a terminal electrode 6a structurally separated from the emitter electrode 6 are provided on the first main surface of the semiconductor substrate of the termination region 30. The emitter electrode 6 and the terminal electrode 6a are electrically connected via a semi-insulating film 33. The semi-insulating film 33 may be, for example, semi-insulating silicon nitride (sinSIN). The terminal electrode 6a is electrically connected to each of the p-type termination well layer 31 and the n⁺-type channel stopper layer 32 via a contact hole of the interlayer insulating film 4 provided on the first main surface of the termination region 30. Further, the termination region 30 is provided with a termination protection film 34 that covers the emitter electrode 6, the terminal electrode 6a, and the semi-insulating film 33. The termination protection film 34 is, for example, polyimide.

### <Method of Manufacturing RC-IGBT>

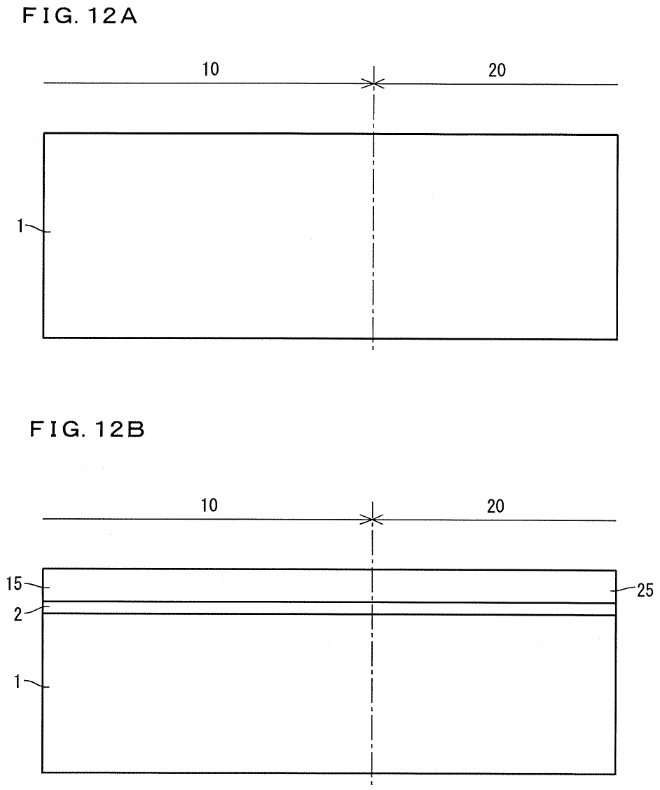

FIGS. 12A to 17B are cross-sectional views illustrating a method of manufacturing a semiconductor device that is an RC-IGBT. FIGS. 12A to 15B are diagrams illustrating a step of mainly forming the front surface side of the boundary region of FIG. 9 of the semiconductor device 100, and FIGS. 16A to 17B are diagrams illustrating a step of mainly forming the back surface side of the boundary region of FIG. 9 of the semiconductor device 100.

First, as illustrated in FIG. 12A, a semiconductor substrate constituting the n⁻-type drift layer 1 is prepared. The semiconductor substrate may be, for example, an FZ wafer manufactured by a floating zone (FZ) method, an MCZ wafer manufactured by a magnetic-field applied CZochralski (MCZ) method, or an n-type wafer containing an n-type impurity. Concentration of an n-type impurity contained in the semiconductor substrate is appropriately selected depending on withstand voltage of a semiconductor device to be manufactured. For example, in a semiconductor device having withstand voltage of 1200 V, concentration of an n-type impurity is adjusted such that specific resistance of the n⁻-type drift layer 1 constituting the semiconductor substrate is about 40 to 120 Ω·cm. As illustrated in FIG. 12A, in the step of preparing the semiconductor substrate, the entire semiconductor substrate is the n-type drift layer 1. By implanting p-type or n-type impurity ions from the first main surface side or the second main surface side of such a semiconductor substrate and then diffusing them into the semiconductor substrate by heat treatment or the like, a p-type or n-type semiconductor layer is appropriately formed, and the semiconductor device 100 is manufactured.

As illustrated in FIG. 12A, the semiconductor substrate constituting the n⁻-type drift layer 1 has a region to be the IGBT region 10 and the diode region 20. Further, although not illustrated, a region to be the termination region 30 and the like is provided around the region to be the IGBT region 10 and the diode region 20. Hereinafter, a method of manufacturing a configuration of the IGBT region 10 and the diode region 20 of the semiconductor device 100 will be mainly described, but the termination region 30 and the like of the semiconductor device 100 may be manufactured by a well-known manufacturing method. For example, in a case where an FLR having the p-type termination well layer 31 as a withstand voltage holding structure is formed in the termination region 30, the FLR may be formed by implanting p-type impurity ions before the IGBT region 10 and the diode region 20 of the semiconductor device 100 are processed. Alternatively, when a p-type impurity is ion-implanted into the IGBT region 10 or the diode region 20 of the semiconductor device 100, p-type impurity ions may be implanted simultaneously to form an FLR.

Next, as illustrated in FIG. 12B, an n-type impurity such as phosphorus (P) is implanted from the first main surface side of the semiconductor substrate to form the n-type carrier storage layer 2. Further, a p-type impurity such as boron (B) is implanted from the first main surface side of the semiconductor substrate to form the p-type base layer 15 and the p-type anode layer 25. The n-type carrier storage layer 2, the p-type base layer 15, and the p-type anode layer 25 are formed by implanting impurity ions into a semiconductor substrate and then diffusing the impurity ions by heat treatment. Since the ion implantation of an n-type impurity and a p-type impurity is performed after mask processing is performed on the first main surface of the semiconductor substrate, various layers are selectively formed on the front surface side of the semiconductor substrate. The n-type carrier storage layer 2, the p-type base layer 15, and the p-type anode layer 25 are formed in the IGBT region 10 and the diode region 20, and are connected to the p-type termination well layer 31 in the termination region 30. The mask processing is processing of applying resist on a semiconductor substrate, forming an opening in a predetermined region of the resist using a photolithography technique, and forming a mask on the semiconductor substrate in order to perform ion implantation or etching on the predetermined region of the semiconductor substrate through the opening. By the mask processing and the ion implantation described above, the n-type carrier storage layer 2, the p-type base layer 15, and the p-type anode layer 25 are selectively formed on the first main surface side of the IGBT region 10 and the diode region 20. Similarly, the p-type termination well layer 31 is selectively formed in the termination region 30.

The p-type impurities of the p-type base layer 15 and the p-type anode layer 25 may be ion-implanted simultaneously. In this case, depths and p-type impurity concentrations of the p-type base layer 15 and the p-type anode layer 25 are the same. Further, the p-type impurities of the p-type base layer 15 and the p-type anode layer 25 may be separately ion-implanted by the mask processing to make depths and p-type impurity concentrations of the p-type base layer 15 and the p-type anode layer 25 different from each other.

The p-type impurities of the p-type termination well layer 31 and the p-type anode layer 25 of the termination region 30 not illustrated in FIG. 12B may be simultaneously ion-implanted. In this case, depths and p-type impurity concentrations of the p-type termination well layer 31 and the p-type anode layer 25 are the same. Alternatively, the p-type impurities of the p-type termination well layer 31 and the p-type anode layer 25 may be separately ion-implanted by the mask processing to make depths and p-type impurity concentrations of the p-type termination well layer 31 and the p-type anode layer 25 different from each other. Alternatively, the p-type impurities of the p-type termination well layer 31 and the p-type anode layer 25 are simultaneously ion-implanted using masks having different opening ratios, so that p-type impurity concentrations of the p-type termination well layer 31 and the p-type anode layer 25 can be made different from each other. In this case, opening ratios of the masks only need to be different by using one or both of the masks as a mesh-like mask. Similarly, the p-type impurities of the p-type termination well layer 31, the p-type base layer 15, and the p-type anode layer 25 can be simultaneously ion-implanted using masks having different opening ratios, so that the p-type impurity concentrations of the p-type termination well layer 31, the p-type base layer 15, and the p-type anode layer 25 can be made different from each other. The p-type termination well layer 31, the p-type base layer 15, and the p-type anode layer 25 may be formed by ion implantation of the p-type impurities at the same time.

Next, as illustrated in FIG. 13A, the n⁺-type source layer 13 is selectively formed on the first main surface side of the p-type base layer 15 in the IGBT region 10 by mask processing and n-type impurity implantation. The n-type impurity to be implanted may be, for example, arsenic (As) or phosphorus (P). Further, the p⁺-type contact layer 14 is selectively formed on the first main surface side of the p-type base layer 15 of the IGBT region 10, and the p⁺-type contact layer 24 is selectively formed on the first main surface side of the p-type anode layer 25 of the diode region 20, by mask processing and p-type impurity implantation. The p-type impurity to be implanted may be, for example, boron (B) or aluminum (Al).

Next, as illustrated in FIG. 13B, a trench 8 that penetrates the p-type base layer 15 and the p-type anode layer 25 from the first main surface side of the semiconductor substrate and reaches the n⁻-type drift layer 1 is formed. In the IGBT region 10, a sidewall of the trench 8 penetrating the n⁺-type source layer 13 includes a part of the n⁺-type source layer 13. In the IGBT region 10, a sidewall of the trench 8 penetrating the p⁺-type contact layer 14 includes a part of the p⁺-type contact layer 14. In the diode region 20, a sidewall of the trench 8 penetrating the p⁺-type contact layer 24 includes a part of the p⁺-type contact layer 24.

For example, the trench 8 is formed by depositing an oxide film of SiO₂ or the like on a semiconductor substrate, forming an opening in the oxide film at a portion where the trench 8 is to be formed by mask processing, and etching the semiconductor substrate using, as a mask, the oxide film on which the opening is formed. In FIG. 13B, the trenches 8 are formed at the same pitch between the IGBT region 10 and the diode region 20, but pitches of the trenches 8 may be made different between the IGBT region 10 and the diode region 20. A pitch and a pattern in plan view of the trenches 8 can be appropriately changed according to a mask pattern of mask processing.

Next, as illustrated in FIG. 14A, the semiconductor substrate is heated in an atmosphere containing oxygen to form an oxide film 9 on an inner wall of the trench 8 and the first main surface of the semiconductor substrate. The oxide film 9 formed on the trench 8 of the IGBT region 10 is the gate trench insulating film 11b of the active trench gate 11 and the dummy trench insulating film 12b of the dummy trench gate 12. Further, the oxide film 9 formed on the trench 8 of the diode region 20 is the diode trench insulating film 21b. The oxide film 9 formed on the first main surface of the semiconductor substrate is removed in a later step except for a portion formed on the trench 8.

Next, as illustrated in FIG. 14B, polysilicon doped with n-type or p-type impurities by chemical vapor deposition (CVD) or the like is deposited on the oxide film 9 in the trench 8 to form the gate trench electrode 11a, the dummy trench electrode 12a, and the diode trench electrode 21a.

Next, as illustrated in FIG. 15A, the interlayer insulating film 4 is formed on the gate trench electrode 11a of the active trench gate 11 of the IGBT region 10. The interlayer insulating film 4 may be, for example, SiO₂. By forming a contact hole in the deposited insulating film to be the interlayer insulating film 4 and removing the oxide film 9 formed on the first main surface of the semiconductor substrate by mask processing, the interlayer insulating film 4 and the like in FIG. 15A are formed. The contact hole of the interlayer insulating film 4 is formed on the n⁺-type source layer 13, the p⁺-type contact layer 14, the p⁺-type contact layer 24, the dummy trench electrode 12a, and the diode trench electrode 21a.

Next, as illustrated in FIG. 15B, the barrier metal 5 is formed on the first main surface of the semiconductor substrate and on the interlayer insulating film 4, and the emitter electrode 6 is further formed on the barrier metal 5. The barrier metal 5 is formed by forming a film of titanium nitride by physical vapor deposition (PVD) or CVD.

The emitter electrode 6 may be formed by, for example, depositing an aluminum silicon alloy (Al—Si-based alloy) on the barrier metal 5 by PVD such as sputtering or vapor deposition. Further, a nickel alloy (Ni alloy) may be further formed on the formed aluminum silicon alloy by electroless plating or electrolytic plating to form the emitter electrode 6. When the emitter electrode 6 is formed by plating, a thick metal film can be easily formed as the emitter electrode 6, so that heat capacity of the emitter electrode 6 can be increased to improve heat resistance. Note that when a nickel alloy is further formed on the emitter electrode 6 by plating processing after the emitter electrode 6 made from an aluminum silicon alloy is formed by PVD, the plating processing for forming the nickel alloy may be performed after processing of the second main surface side of the semiconductor substrate.

Next, as illustrated in FIG. 16A, the second main surface side of the semiconductor substrate is ground to thin the semiconductor substrate to designed predetermined thickness. Thickness of the semiconductor substrate after grinding may be, for example, 80 μm to 200 μm.

Next, as illustrated in FIG. 16B, an n-type impurity is implanted from the second main surface side of the semiconductor substrate to form the n-type buffer layer 3. Furthermore, a p-type impurity is implanted from the second main surface side of the semiconductor substrate to form the p-type collector layer 16. The n-type buffer layer 3 may be formed in the IGBT region 10, the diode region 20, the termination region 30, and the like, or may be formed only in the IGBT region 10 or the diode region 20. The n-type buffer layer 3 may be formed by, for example, implanting phosphorus (P) ions, implanting protons (H+), or implanting both protons and phosphorus. Protons can be injected from the second main surface of the semiconductor substrate to a deep position with relatively low acceleration energy. Further, by changing acceleration energy, depth to which protons are injected can be relatively easily changed. For this reason, when the n-type buffer layer 3 is formed of protons, if implantation is performed a plurality of times by changing acceleration energy, the n-type buffer layer 3 thicker in a thickness direction of the semiconductor substrate than that formed of phosphorus can be formed.

Further, since phosphorus can increase an activation rate as an n-type impurity as compared with protons, when the n-type buffer layer 3 is formed of phosphorus, punch-through of a depletion layer can be suppressed even in a thinned semiconductor substrate. In order to further thin the semiconductor substrate, it is preferable to form the n-type buffer layer 3 by injecting both protons and phosphorus, and in this case, protons are injected to a position deeper from the second main surface than phosphorus.

The p-type collector layer 16 may be formed by injecting boron (B), for example. The p-type collector layer 16 is also formed in the termination region 30, and the p-type collector layer 16 in the termination region 30 becomes the p-type termination collector layer 16a. After ion implantation from the second main surface side of the semiconductor substrate, the second main surface is irradiated with laser for laser annealing, so that the implanted boron is activated to form the p-type collector layer 16. At this time, phosphorus injected at a relatively shallow position from the second main surface of the semiconductor substrate is also activated at the same time. On the other hand, since protons are activated at relatively low annealing temperature such as 350° C. to 500° C., it is necessary to pay attention so that temperature of the entire semiconductor substrate does not become higher than 350° C. to 500° C. except for a step for activating protons after injection of protons. Since the laser annealing can make temperature high only in the vicinity of the second main surface of the semiconductor substrate, the laser annealing can be used for activating an n-type impurity and a p-type impurity even after protons are implanted.

Next, as illustrated in FIG. 17A, the n⁺-type cathode layer 26 is formed on the second main surface side of the diode region 20. The n⁺-type cathode layer 26 may be formed by injecting, for example, arsenic (As), phosphorus (P), or the like. As illustrated in FIG. 17A, an n-type impurity is selectively implanted from the second main surface side by mask processing such that a boundary between the p-type collector layer 16 and the n⁺-type cathode layer 26 is located at a position at the distance U1 from a boundary between the IGBT region 10 and the diode region 20 toward the diode region 20 side. An implantation amount of an n-type impurity for forming the n⁺-type cathode layer 26 is larger than an implantation amount of a p-type impurity for forming the p-type collector layer 16. In FIG. 17A, depths of the p-type collector layer 16 and the n⁺-type cathode layer 26 from the second main surface are illustrated to be the same, but depth of the n⁺-type cathode layer 26 is equal to or more than depth of the p-type collector layer 16. In a region where the n⁺-type cathode layer 26 is formed, since it is necessary to inject an n-type impurity into a region into which a p-type impurity is implanted to finally make the region n-type, concentration of the n-type impurity is higher than concentration of the p-type impurity implanted in the entire region where the n⁺-type cathode layer 26 is formed.

Next, as illustrated in FIG. 17B, the collector electrode 7 is formed on the second main surface of the semiconductor substrate. The collector electrode 7 is formed over the entire surface of the second main surface, such as the IGBT region 10, the diode region 20, and the termination region 30. Further, the collector electrode 7 may be formed over the entire surface of the second main surface of an n-type wafer as a semiconductor substrate.

The collector electrode 7 may be formed by depositing an aluminum silicon alloy (Ai-Si-based alloy), titanium (Ti), or the like by PVD such as sputtering or vapor deposition, or may be formed by laminating a plurality of pieces of metal such as an aluminum silicon alloy, titanium, nickel, or gold. Further, the collector electrode 7 may be formed by further forming a metal film by electroless plating or electrolytic plating on the metal film formed by PVD.

The semiconductor device 100 is manufactured by the above steps. A plurality of the semiconductor devices 100 are manufactured in a state of being integrated in a matrix on a semiconductor substrate such as one n-type wafer. For this reason, the semiconductor device 100 is individually cut by laser dicing or blade dicing.

### <Temperature Sensing Unit 50>

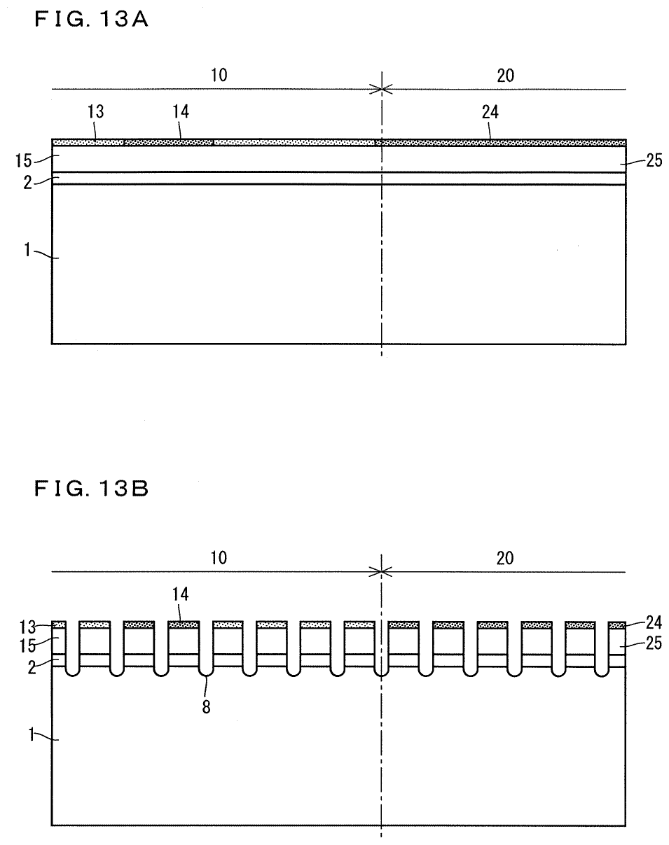

FIG. 18 is a cross-sectional view illustrating a configuration of the semiconductor device according to the first preferred embodiment. The semiconductor device according to the first preferred embodiment includes not only the RC-IGBT described above but also the temperature sensing unit 50 illustrated in FIGS. 2, 3, and 18 as a polysilicon element.

As illustrated in FIG. 18, the semiconductor device according to the first preferred embodiment includes the temperature sensing unit 50, a semiconductor substrate 51, a lower insulating film 52, an upper insulating film 54, a cathode electrode 55, and an anode electrode 56.

The semiconductor substrate 51 is the semiconductor substrate described above, and has a front surface 51a which is the first main surface. The temperature sensing unit 50 is provided on a region other than a main current conduction region such as the IGBT region 10 on the front surface 51a of the semiconductor substrate 51 via the lower insulating film 52. The temperature sensing unit 50 includes an n⁺-type cathode region 53a, a p⁺-type anode region 53b, and a p⁻-type drift region 53c. The n⁺-type cathode region 53a, the p⁺-type anode region 53b, and the p-type drift region 53c are provided on the lower insulating film 52.

An impurity of the n⁺-type cathode region 53a may be the same as an impurity of the n⁺-type source layer 13 of FIG. 9. Further, an impurity of the p⁺-type anode region 53b may be the same as an impurity of the p⁺-type contact layer 14 of FIG. 9. The p-type drift region 53c is provided between the n⁺-type cathode region 53a and the p⁺-type anode region 53b, and impurity concentration of the p″-type drift region 53c is lower than impurity concentration of the p⁺-type anode region 53b.

The upper insulating film 54 covers an upper portion and a side portion of the temperature sensing unit 50 and has a contact hole for exposing the n⁺-type cathode region 53a and a contact hole for exposing the p⁺-type anode region 53b. Note that the lower insulating film 52 and the upper insulating film 54 may be thermal oxide films.

The cathode electrode 55 is electrically connected to the n⁺-type cathode region 53a in a contact hole exposing the n⁺-type cathode region 53a. The anode electrode 56 is electrically connected to the p⁺-type anode region 53b in a contact hole exposing the p⁺-type anode region 53b. The temperature sensing unit 50 as described above functions as a temperature sensing diode.

Note that in FIG. 18, width of the n⁺-type cathode region 53a in a cross-sectional view, that is, length in an in-plane direction changes with respect to an upward direction which is a direction from a back surface of the semiconductor substrate 51 toward the front surface 51a, but the present invention is not limited to this. Further, in the example of FIG. 18, width of the n⁺-type cathode region 53a in a cross-sectional view monotonously increases continuously with respect to the upward direction, but may change stepwise with respect to the upward direction. In the configuration in which width of the n⁺-type cathode region 53a in a cross-sectional view changes with respect to a direction from a back surface of the semiconductor substrate 51 toward the front surface 51a, a junction area of pn junction can be increased.

### <Wiring of Temperature Sensing Unit>

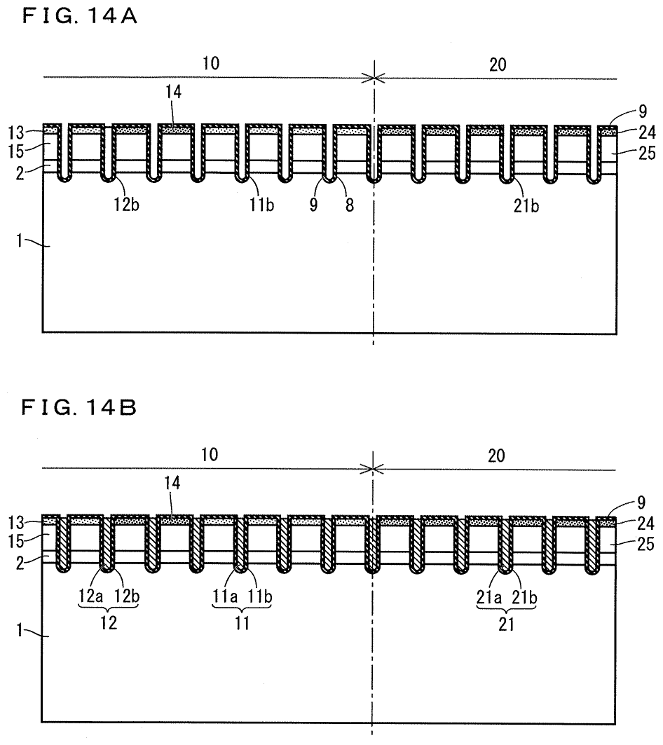

FIG. 19 is a plan view (top view) schematically illustrating a configuration of the semiconductor device according to the first preferred embodiment. FIG. 19 is a diagram schematically illustrating the configuration specifically illustrated in FIGS. 2 and 3, and the configuration of FIG. 19 is slightly different from the configuration of FIGS. 2 and 3. Note that a dot-hatched region in FIG. 19 indicates an effective region such as a cell region.

As illustrated in FIG. 19, the emitter electrode 6 illustrated in FIG. 4 and the like is selectively provided on a front surface of the semiconductor substrate 51. In the first preferred embodiment, generally, one of the emitter electrode 6 is provided on each of the left and right sides of the semiconductor substrate 51. Note that although not illustrated in FIG. 19, a plurality of second wire bond portions connected to a plurality of wires through which emitter current (that is, main current passing through a channel of an IGBT and the emitter electrode 6) flows are provided on the emitter electrode 6. In such a configuration, an area of a path through which the emitter current passes can be made large.

The temperature sensing unit 50 is provided on a front surface of the semiconductor substrate 51 and adjacent to the emitter electrode 6. In the first preferred embodiment, the temperature sensing unit 50 is provided on the inner side than a terminal end of the semiconductor substrate 51 in plan view and between the emitter electrodes 6 on the left and right.

A shape of the emitter electrode 6 includes a protruding portion 61b protruding from a main body portion 61a of the emitter electrode 6 toward the outside of the emitter electrode 6 in plan view. In the first preferred embodiment, the protruding portion 61b is provided at a terminal end (that is, the termination region 30) of the semiconductor substrate 51 in plan view, and protrudes in a direction (first direction) opposite to a Y direction.

A cathode wiring 62 which is a sense wiring is provided along the emitter electrode 6. One end of the cathode wiring 62 is connected to the temperature sensing unit 50, and another end of the cathode wiring 62 is connected to the emitter electrode 6 (protruding portion 61b). According to such a configuration, since a part of the emitter electrode 6 can be used as a cathode pad which is a type of the electrode pad 41 in FIGS. 2 and 3, not only an area required only for a cathode pad can be deleted, but also reduction of an ineffective region and improvement of assemblability can be expected.

In the first preferred embodiment, the cathode wiring 62 includes a first sense wiring portion 62a, a second sense wiring portion 62b, and a bent portion 62c. The first sense wiring portion 62a extends in a direction (first direction) opposite to the Y direction from the inner side to a terminal end of the semiconductor substrate 51 between the emitter electrodes 6 on the left and right in plan view. The second sense wiring portion 62b extends from the first sense wiring portion 62a to the connection portion 63 between the emitter electrode 6 and the cathode wiring 62 along an X direction (second direction) different from the extending direction (first direction) of the first sense wiring portion 62a at a terminal end of the semiconductor substrate 51. The bent portion 62c is a portion between the first sense wiring portion 62a and the second sense wiring portion 62b.

An anode wiring 64 is provided adjacent to the emitter electrode 6, similarly to the cathode wiring 62. One end of the anode wiring 64 is connected to the temperature sensing unit 50, and another end of the anode wiring 64 is connected to an anode pad 65 which is a type of the electrode pad 41 in FIGS. 2 and 3. A wire bond portion 66 connected to a wire (not illustrated) for reading anode potential of the temperature sensing unit 50 is provided on the anode pad 65.

Note that in the first preferred embodiment, in a region between the emitter electrodes 6 on the left and right where the first sense wiring portion 62a is provided, the anode wiring 64 which is a type of a wiring having potential different from that of the cathode wiring 62 is provided, but the present invention is not limited to this. In this region, for example, a gate wiring or the like may also be provided as a wiring of different potential which is a wiring having potential different from that of the cathode wiring 62. Further, in a region from the first sense wiring portion 62a to the connection portion 63 where the second sense wiring portion 62b is provided, for example, a gate wiring or the like may also be provided as a wiring of different potential which is a wiring having potential different from that of the cathode wiring 62.

A first wire bond portion 67 connected to a wire (not illustrated) for reading cathode potential of the temperature sensing unit 50 is provided on the emitter electrode 6 and adjacent to the connection portion 63 between the emitter electrode 6 (protruding portion 61b) and the cathode wiring 62. In the first preferred embodiment, a distance from the connection portion 63 to the first wire bond portion 67 is shorter than a distance from the bent portion 62c to the connection portion 63.

The gate pad 41c in FIGS. 2 and 3 separated from the emitter electrode 6 is provided on the side opposite to the cathode wiring 62 with respect to the connection portion 63. A wire bond portion 69 to which a wire (not illustrated) for supplying gate drive voltage to the gate trench electrode 11a is connected is provided on the gate pad 41c. Note that as the electrode pad in FIGS. 2 and 3, an electrode pad other than the emitter electrode 6 used as a cathode pad, the anode pad 65, and the gate pad 41c may be provided.

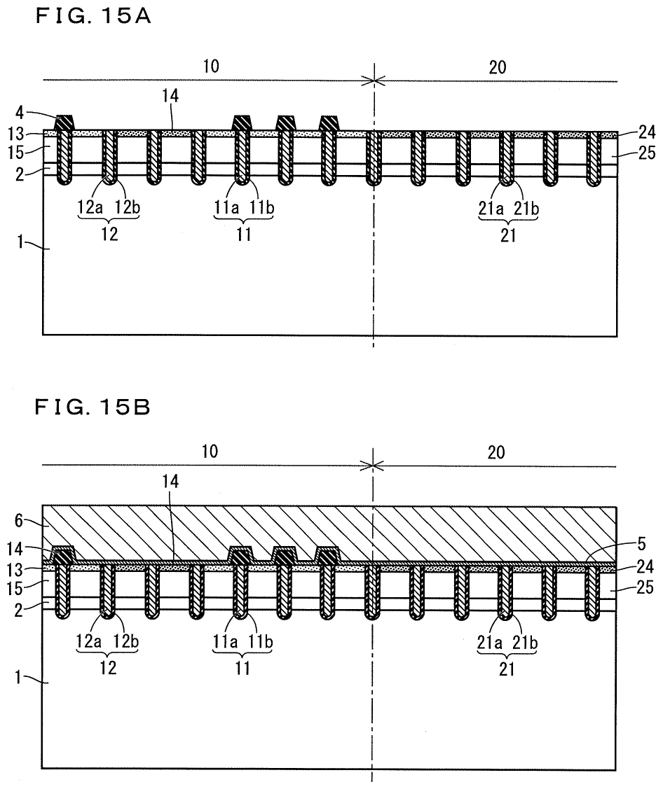

FIG. 20 is a plan view schematically illustrating a configuration of a related device related to the semiconductor device according to the first preferred embodiment, and is a plan view corresponding to FIG. 19. In the related device of FIG. 20, the emitter electrode 6 is not provided with the protruding portion 61b. For this reason, a distance between the first wire bond portion 67 and the connection portion 70 between the cathode wiring 62 and the emitter electrode 6 in FIG. 20 is longer than a distance between the connection portion 63 and the first wire bond portion 67 in FIG. 19. In such a configuration, since cathode potential of the temperature sensing unit 50 read from a wire of the first wire bond portion 67 is strongly affected by emitter current flowing through the emitter electrode 6, cathode potential of the temperature sensing unit 50 cannot be measured correctly.

On the other hand, in the first preferred embodiment, a distance from the connection portion 63 to the first wire bond portion 67 is shorter than a distance from the bent portion 62c to the connection portion 63. According to such a configuration, since influence that cathode potential of the temperature sensing unit 50 read from a wire of the first wire bond portion 67 receives from emitter current flowing through the emitter electrode 6 can be reduced, cathode potential of the temperature sensing unit 50 can be measured correctly.

Further, in the first preferred embodiment, the gate pad 41c separated from the emitter electrode 6 is provided on the side opposite to the cathode wiring 62 with respect to the connection portion 63. According to such a configuration, it is possible to prevent emitter current flowing through the emitter electrode 6 from flowing in a region on the side opposite to the cathode wiring 62 with respect to the connection portion 63. By this, since influence that cathode potential of the temperature sensing unit 50 read from a wire of the first wire bond portion 67 receives from emitter current flowing through the emitter electrode 6 can be further reduced, cathode potential of the temperature sensing unit 50 can be further measured correctly.

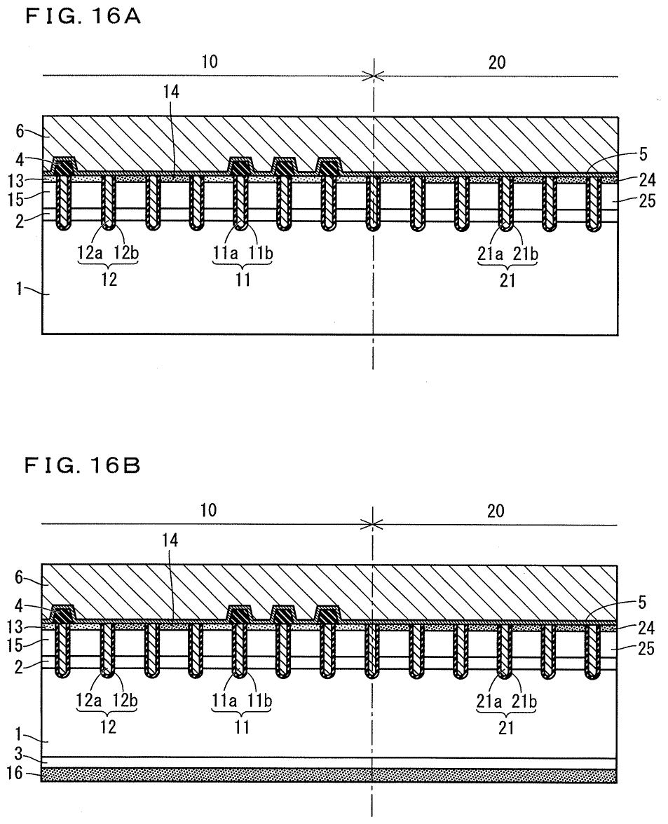

Note that although the emitter electrode 6 includes the protruding portion 61b in the above description, the emitter electrode 6 does not need to include the protruding portion 61b as illustrated in FIG. 21. This similarly applies to second and subsequent preferred embodiments.

### Second Preferred Embodiment

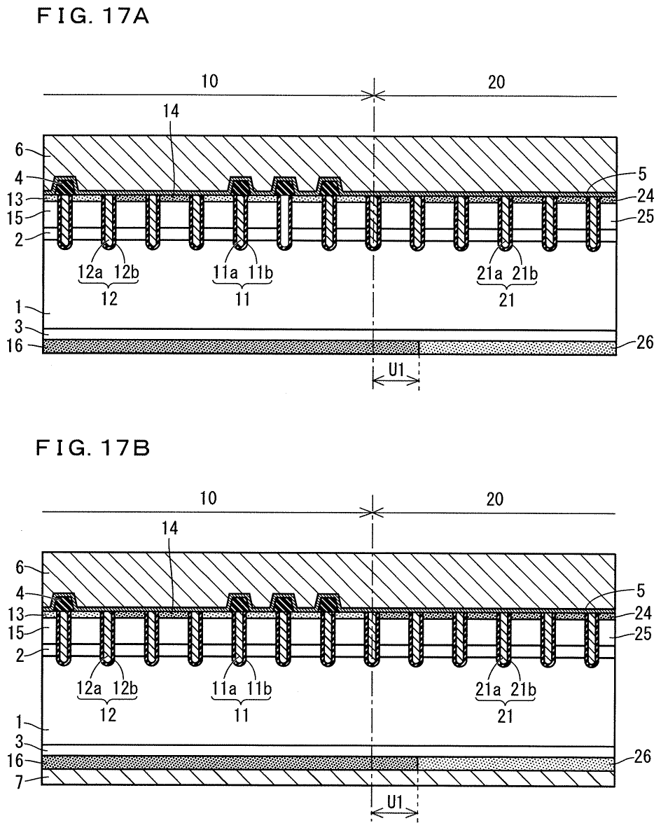

FIG. 22 is a plan view schematically illustrating a configuration of the semiconductor device according to the second preferred embodiment, and is a plan view corresponding to FIG. 19.

In the first preferred embodiment, the protruding portion 61b protrudes in a direction (first direction) opposite to the Y direction. On the other hand, in the second preferred embodiment, the protruding portion 61b protrudes in the X direction (second direction).

Further, in the first preferred embodiment, the cathode wiring 62 extends in a direction (first direction) opposite to the Y direction, and extends in the X direction (second direction) by being bent in the middle. On the other hand, in the second preferred embodiment, the cathode wiring 62 is not bent in the middle, and extends in a direction (first direction) opposite to the Y direction from the inner side of the semiconductor substrate 51 to the protruding portion 61b at a terminal end in plan view. Further, in the second preferred embodiment, a distance from the connection portion 63 to the first wire bond portion 67 is shorter than a distance from the temperature sensing unit 50 to the connection portion 63. According to the present the second preferred embodiment as described above, similarly to the first preferred embodiment, cathode potential of the temperature sensing unit 50 can be accurately measured.

Note that in the second preferred embodiment, the anode wiring 64, which is a type of a wiring having potential different from that of the cathode wiring 62, is provided in a region between the emitter electrodes 6 on the left and right where the cathode wiring 62 is provided, but the present invention is not limited to this. In this region, for example, a gate wiring or the like may also be provided as a wiring of different potential which is a wiring having potential different from that of the cathode wiring 62. Further, the cathode wiring 62 may be slightly bent as long as the cathode wiring 62 extends in a direction (first direction) opposite to the Y direction from the inner side of the semiconductor substrate 51 to the emitter electrode 6 at a terminal end in plan view.

### Third Preferred Embodiment

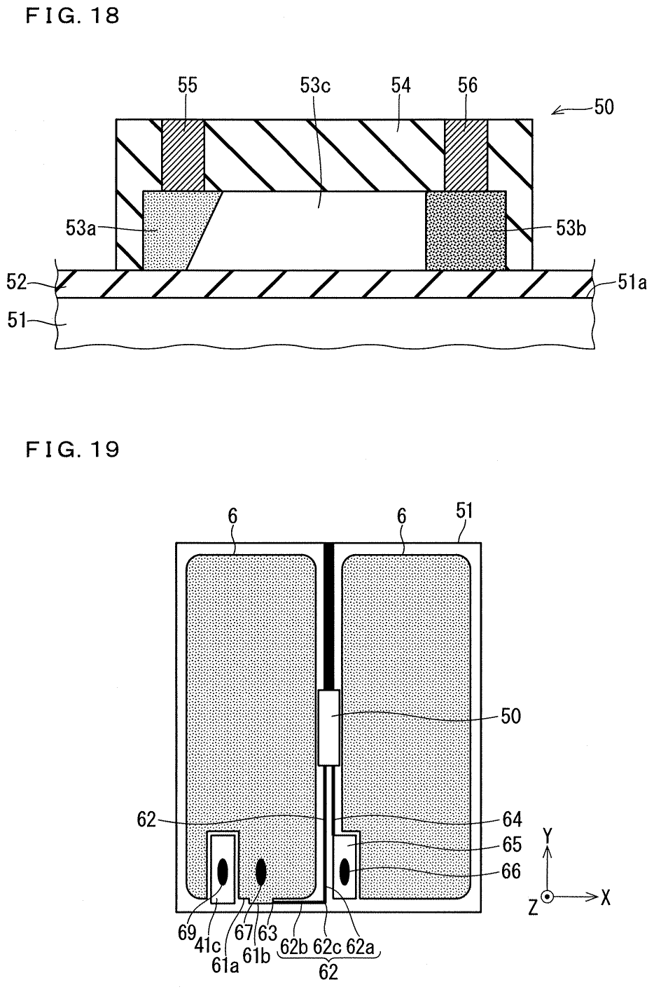

FIG. 23 is an enlarged plan view schematically illustrating a configuration of the semiconductor device according to a third preferred embodiment, and is an enlarged plan view of a periphery of the connection portion 63 in FIG. 19. Note that FIG. 23 illustrates a plurality of second wire bond portions 73 connected to a wire (not illustrated) through which emitter current flows. A plurality of the second wire bond portions 73 are provided on the emitter electrode 6 on the side opposite to the connection portion 63 with respect to the first wire bond portion 67.

In the third preferred embodiment, as indicated by a dotted line in FIG. 23, the cathode wiring 62, the connection portion 63, and the emitter electrode 6 as a whole have a U shape in plan view. In a slit-shaped portion 72 in a U shape, an insulating member is provided, and various electrodes such as a gate electrode do not exist. According to such a configuration, an area of the emitter electrode 6 can be increased as much as possible. If the slit-shaped portion 72 is made as thin as possible, this effect can be enhanced. Note that, although the third preferred embodiment is applied to the configuration of the first preferred embodiment in FIG. 19, the third preferred embodiment may be applied to the configuration of the second preferred embodiment in FIG. 22.

### Fourth Preferred Embodiment

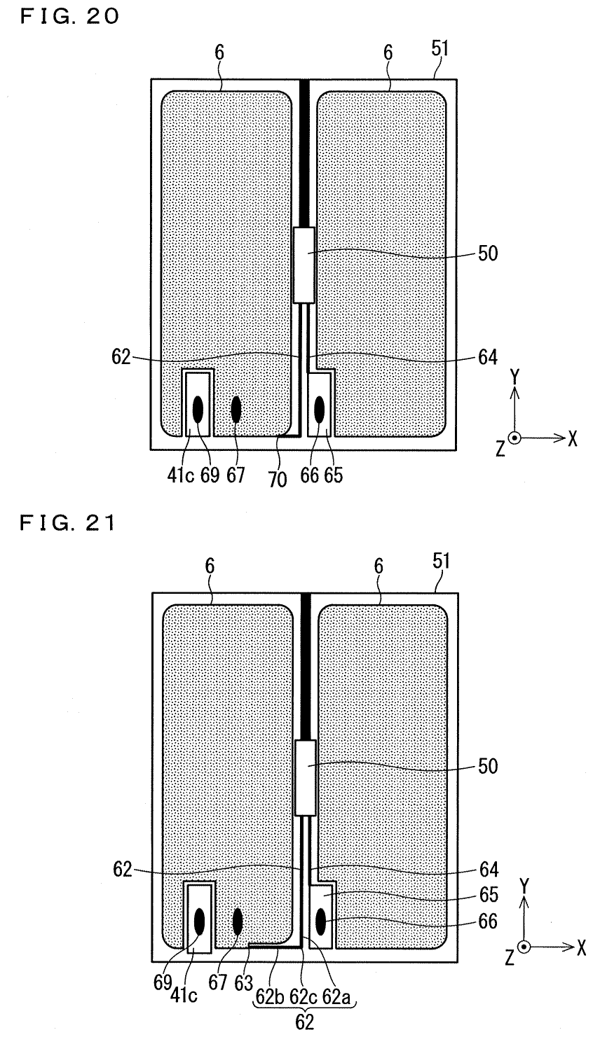

FIG. 24 is an enlarged plan view schematically illustrating a configuration of the semiconductor device according to a fourth preferred embodiment, and is an enlarged plan view corresponding to FIG. 23.

In the fourth preferred embodiment, an active cell is provided on the semiconductor substrate 51 in a quadrangle as indicated by a broken line in FIG. 24 with a line segment 75 between the connection portion 63 and the first wire bond portion 67 as a diagonal line. The active cell corresponds to, for example, a part of the IGBT region 10.

Emitter current flowing through the active cell flows toward a plurality of wires (a plurality of main emitter wirings) (not illustrated) connected to the emitter electrode 6 by a plurality of the second wire bond portions 73. At this time, in a quadrangle provided with the active cell, cathode potential of the temperature sensing unit 50 read from a wire of the first wire bond portion 67 is strongly affected by emitter current flowing through the emitter electrode 6.

In view of the above, in the fourth preferred embodiment, since a distance between the connection portion 63 and the first wire bond portion 67 is shortened so that ΔV=Is×ρ×L<0.7×N is satisfied, the above influence can be reduced. In the above equation, L is length of the line segment 75 that is a diagonal line, Is is current density in a cross-sectional direction flowing between the connection portion 63 and the first wire bond portion 67, p is specific resistance of the emitter electrode 6, N is the number of series of diodes included in the temperature sensing unit 50, and ΔV is voltage between the connection portion 63 and the first wire bond portion 67.

In the above equation, 0.7 is a value of built-in potential of silicon. Temperature of the temperature sensing unit 50 is measured based on a difference between built-in potentials before and after temperature of the temperature sensing unit 50 changes. In order to enable such measurement, in the fourth preferred embodiment, the voltage ΔV is adjusted to be a value within a value of the built-in potential by the above equation. In a case where the number of diodes included in the temperature sensing unit 50 is N, the voltage ΔV is adjusted to be a value within a total value of built-in potentials corresponding to the number of diodes by the above equation in the fourth preferred embodiment. In the fourth preferred embodiment, since the above-described adjustment is realized by the above equation, temperature of the temperature sensing unit 50 can be appropriately measured.

Note that in the fourth preferred embodiment, metal of the emitter electrode 6 is aluminum, and the specific resistance p of the emitter electrode 6 is specific resistance of aluminum, but the specific resistance p may be changed depending on the metal used for the emitter electrode 6.

### Fifth Preferred Embodiment

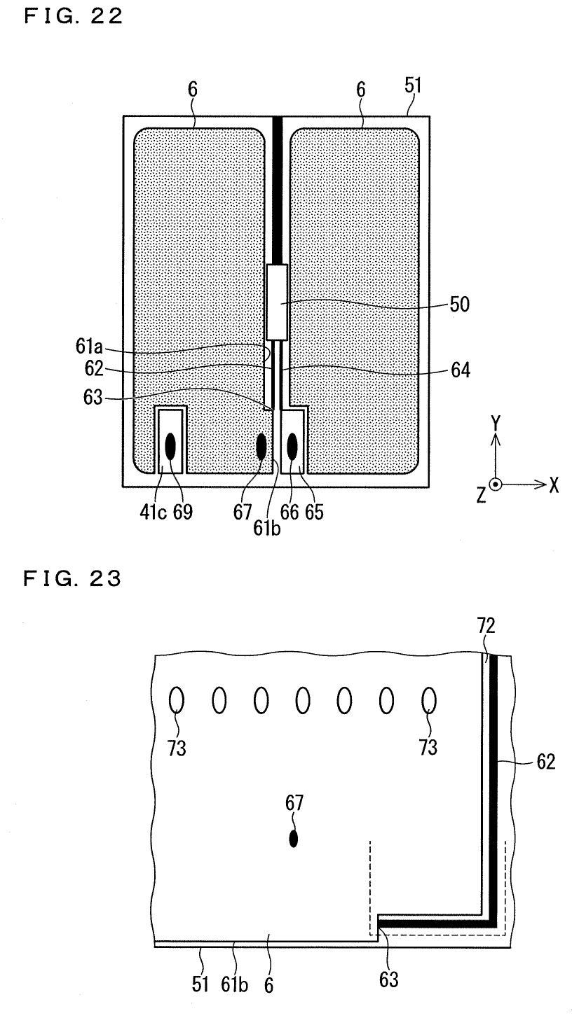

FIG. 25 is an enlarged plan view schematically illustrating a configuration of the semiconductor device according to a fifth preferred embodiment, and is an enlarged plan view corresponding to FIG. 22.

FIG. 25 illustrates a line portion 76 from the first wire bond portion 67 to an end of the emitter electrode 6 in a straight line extending from the second wire bond portion 73 to the end of the emitter electrode 6 through the first wire bond portion 67. In the fifth preferred embodiment, an active cell is provided on a semiconductor substrate in a substantially triangular region surrounded by the line portion 76 and an end of the emitter electrode 6. In a quadrangle provided with the active cell as described above, similarly to the fourth preferred embodiment, cathode potential of the temperature sensing unit 50 read from a wire of the first wire bond portion 67 is strongly affected by emitter current flowing through the emitter electrode 6.

In view of the above, in the fifth preferred embodiment, since a distance between the connection portion 63 and the first wire bond portion 67 is shortened so that ΔV=Is×ρ×L<0.7×N is satisfied, the above influence can be reduced. Note that in the above equation, L is length of the line portion 76. Other values of Is, ρ, N, and ΔV are similar to those in the fourth preferred embodiment. According to such a configuration, since the voltage ΔV is adjusted to be a value within a total value of built-in potentials corresponding to the number of diodes included in the temperature sensing unit 50, temperature of the temperature sensing unit 50 can be appropriately measured.

### Variation of Fourth and Fifth Preferred Embodiments

The voltage ΔV may be 50% or less of a range between upper and lower limits of standard voltage of the temperature sensing unit 50. For example, in a case where a lower limit and an upper limit of standard voltage of the temperature sensing unit 50 are 1.8 V and 2.2 V, the voltage ΔV may be 0.2 V (=0.4 V×50%). In such a configuration, temperature measurement accuracy of the temperature sensing unit 50 can be enhanced as compared with a configuration in which the voltage ΔV exceeds 50% of the above range of the temperature sensing unit 50. Further, in a configuration in which the voltage ΔV is 30% or less of the above range of the temperature sensing unit 50, temperature measurement accuracy of the temperature sensing unit 50 can be enhanced as compared with a configuration in which the voltage ΔV exceeds 30% of the above range of the temperature sensing unit 50. Further, in a configuration in which the voltage ΔV is 10% or less of the above range of the temperature sensing unit 50, temperature measurement accuracy of the temperature sensing unit 50 can be enhanced as compared with a configuration in which the voltage ΔV exceeds 10% of the above range of the temperature sensing unit 50. Further, in a configuration in which the voltage ΔV is 1% or less of the above range of the temperature sensing unit 50, temperature measurement accuracy of the temperature sensing unit 50 can be enhanced as compared with a configuration in which the voltage ΔV exceeds 1% of the above range of the temperature sensing unit 50.

### Sixth Preferred Embodiment

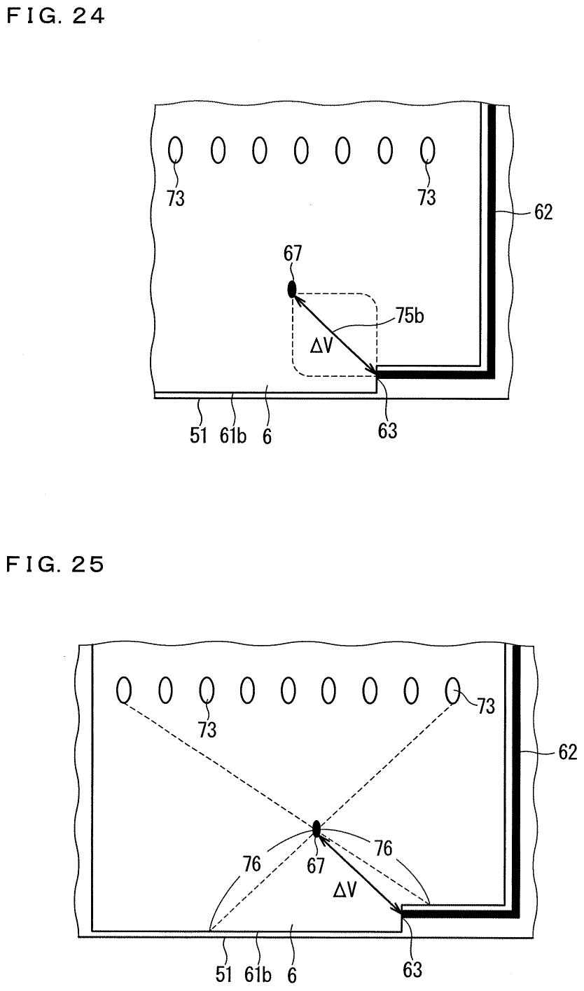

FIG. 26 is a plan view schematically illustrating a configuration of the semiconductor device according to a sixth preferred embodiment, and is a plan view corresponding to FIG. 19.

In the sixth preferred embodiment, an insulating film 78 covering the emitter electrode 6 and the front surface 51a of the semiconductor substrate 51 is provided. Note that in FIG. 26, the emitter electrode 6 covered with the insulating film 78 is indicated by a dotted line.

The insulating film 78 has openings 78a, 78b, 78c, and 78d. The opening 78a exposes the second wire bond portion 73 in FIGS. 23 and 24. The opening 78b exposes the first wire bond portion 67. The opening 78c exposes the wire bond portion 66 of the anode pad 65. The opening 78d exposes the wire bond portion 69 of the gate pad 41c. According to such a configuration, influence of an external factor can be reduced by the insulating film 78.

Note that the insulating film 78 may cover the emitter electrode 6 and the front surface 51a in at least a partial region other than a region between the first wire bond portion 67 and an end (that is, a terminal end) of the semiconductor substrate 51 while exposing the first wire bond portion 67. According to such a configuration, the first wire bond portion 67 can be located farther from the second wire bond portion 73 by the amount that the insulating film 78 is provided. For this reason, it is possible to reduce influence of emitter current flowing through the emitter electrode 6 on cathode potential of the temperature sensing unit 50 read from a wire of the first wire bond portion 67.

### Seventh Preferred Embodiment

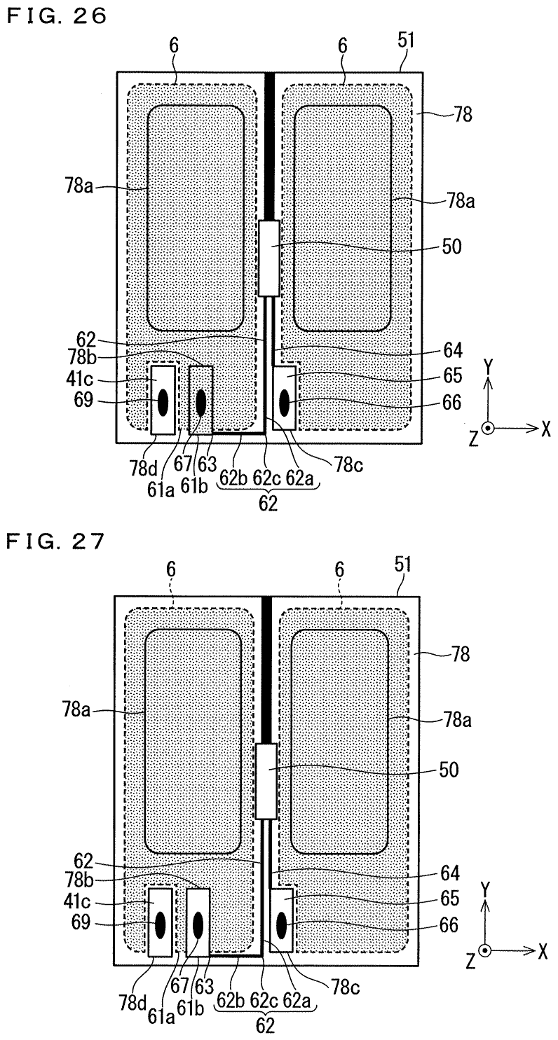

FIG. 27 is a plan view schematically illustrating a configuration of the semiconductor device according to a seventh preferred embodiment, and is a plan view corresponding to FIG. 19. Note that in FIG. 27, the insulating film 78 described in the sixth preferred embodiment is provided, but this is not essential in the seventh preferred embodiment.

In the seventh preferred embodiment, a region where the first wire bond portion 67 is provided in the semiconductor substrate 51 is not dot-hatched and is an ineffective region of the p-type termination well layer 31 and the like. According to such a configuration, it is possible to reduce influence of emitter current flowing through the emitter electrode 6 on cathode potential of the temperature sensing unit 50 read from a wire of the first wire bond portion 67.

### Eighth Preferred Embodiment

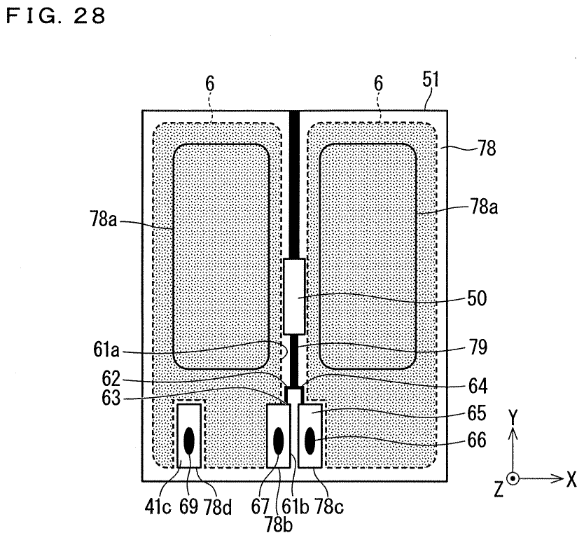

FIG. 28 is a plan view schematically illustrating a configuration of the semiconductor device according to an eighth preferred embodiment, and is a plan view corresponding to FIG. 19. Note that in FIG. 28, the insulating film 78 described in the sixth preferred embodiment is provided, but this is not essential in the eighth preferred embodiment. Further, in FIG. 28, similarly to the seventh preferred embodiment, a region where the first wire bond portion 67 is provided in the semiconductor substrate 51 is an ineffective region, but this is not essential in the eighth preferred embodiment.

In the eighth preferred embodiment, the anode wiring 64 as a wiring overlaps at least a part of the cathode wiring 62 in plan view. For example, in an overlapping portion 79 of FIG. 28, on one of the cathode wiring 62 and the anode wiring 64, the other is provided with an insulating film interposed between them, and the cathode wiring 62 and the anode wiring 64 overlap in a Z direction of FIG. 28 in a state of being insulated from each other. According to such a configuration, since areas of the cathode wiring 62 and the anode wiring 64 in plan view can be reduced, a region of an active cell or the like can be enlarged, for example.

### Ninth Preferred Embodiment

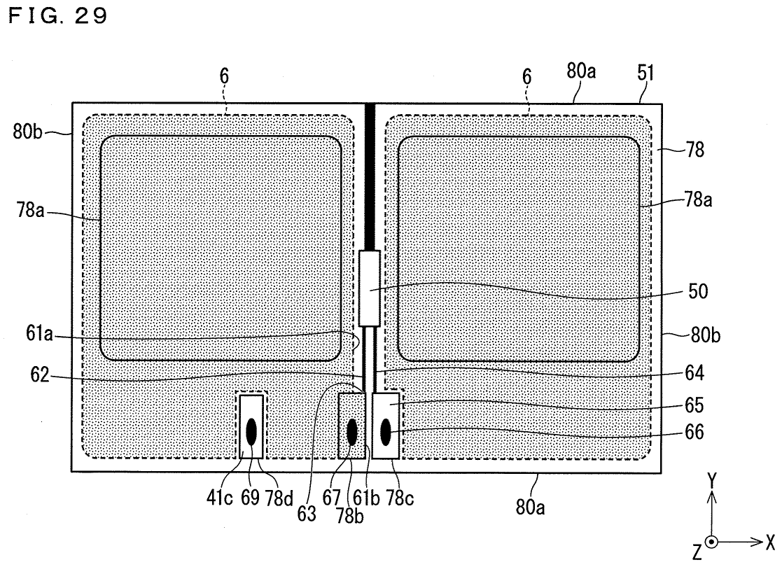

FIG. 29 is a plan view schematically illustrating a configuration of the semiconductor device according to a ninth preferred embodiment, and is a plan view corresponding to FIG. 19. Note that in FIG. 29, the insulating film 78 described in the sixth preferred embodiment is provided, but this is not essential in the ninth preferred embodiment.

In the ninth preferred embodiment, the semiconductor substrate 51 has a rectangular shape in plan view, a long side 80a of the semiconductor substrate 51 extends along the X direction, and a short side 80b of the semiconductor substrate 51 extends along the Y direction. Then, the first wire bond portion 67 is provided on the long side 80a side of the semiconductor substrate 51. According to such a configuration, since lengths of the cathode wiring 62 and the anode wiring 64 can be shortened as compared with a configuration in which the first wire bond portion 67 is provided on the short side 80b side of the semiconductor substrate 51, a region of an active cell and the like can be enlarged, for example.

Note that, in the present disclosure in English, ‘a’ and ‘an’ mean one or more. For this reason, ‘a’, ‘an’, ‘one or more’ and ‘at least one’ can be used interchangeably.

Note that the preferred embodiments and the variations can be freely combined, and the preferred embodiments and the variations can be appropriately modified or omitted.

Hereinafter, various aspects of the present disclosure will be collectively described as an appendix.

### (Appendix 1)

A semiconductor device, comprising:
a semiconductor substrate having a first main surface;
an emitter electrode selectively provided on the first main surface;
a temperature sensing unit provided on the first main surface and adjacent to the emitter electrode further on an inner side than a terminal end of the semiconductor substrate in plan view;
a sense wiring having one end connected to the temperature sensing unit and another end connected to the emitter electrode at the terminal end of the semiconductor substrate, the sense wiring being provided along the emitter electrode; and
a first wire bond portion provided on the emitter electrode and adjacent to a connection portion between the emitter electrode and the sense wiring, wherein
the sense wiring includes:
a first sense wiring portion extending in a first direction from the inner side of the semiconductor substrate to the terminal end in plan view;
a second sense wiring portion extending at the terminal end from the first sense wiring portion to the connection portion along a second direction different from the first direction of the first sense wiring portion; and
a bent portion between the first sense wiring portion and the second sense wiring portion, and
a distance from the connection portion to the first wire bond portion is shorter than a distance from the bent portion to the connection portion.

### (Appendix 2)

A semiconductor device, comprising:
a semiconductor substrate having a first main surface;
an emitter electrode selectively provided on the first main surface;
a temperature sensing unit provided on the first main surface and adjacent to the emitter electrode further on an inner side than a terminal end of the semiconductor substrate in plan view;
a sense wiring having one end connected to the temperature sensing unit and another end connected to the emitter electrode at the terminal end of the semiconductor substrate, the sense wiring being provided along the emitter electrode; and
a first wire bond portion provided on the emitter electrode and adjacent to a connection portion between the emitter electrode and the sense wiring, wherein
the sense wiring extends in a first direction from the inner side of the semiconductor substrate to the terminal end in plan view, and
a distance from the connection portion to the first wire bond portion is shorter than a distance from the temperature sensing unit to the connection portion.

### (Appendix 3)

A semiconductor device, comprising:
a semiconductor substrate having a first main surface;
an emitter electrode selectively provided on the first main surface;
a temperature sensing unit provided on the first main surface and adjacent to the emitter electrode;
a sense wiring having one end connected to the temperature sensing unit and another end connected to the emitter electrode, the sense wiring being provided along the emitter electrode; and
a first wire bond portion provided on the emitter electrode and adjacent to a connection portion between the emitter electrode and the sense wiring, wherein
the sense wiring, the connection portion, and the emitter electrode as a whole have a U shape in plan view, and
an electrode does not exist in a portion in the U shape.

### (Appendix 4)

A semiconductor device, comprising:
a semiconductor substrate having a first main surface;
an emitter electrode selectively provided on the first main surface;
a temperature sensing unit provided on the first main surface;
a sense wiring having one end connected to the temperature sensing unit and another end connected to the emitter electrode; and
a first wire bond portion provided on the emitter electrode and adjacent to a connection portion between the emitter electrode and the sense wiring, wherein
an active cell is provided on the semiconductor substrate in a quadrangle having a line segment between the connection portion and the first wire bond portion as a diagonal line, and
when length of the diagonal line is L, current density in a cross-sectional direction flowing between the connection portion and the first wire bond portion is Is, specific resistance of the emitter electrode is ρ, a number of series of diodes included in the temperature sensing unit is N, and voltage between the connection portion and the first wire bond portion is ΔV, ΔV=Is×ρ×L<0.7×N holds.

### (Appendix 5)

A semiconductor device, comprising:
a semiconductor substrate having a first main surface;
an emitter electrode selectively provided on the first main surface;
a temperature sensing unit provided on the first main surface;
a sense wiring having one end connected to the temperature sensing unit and another end connected to the emitter electrode;
a first wire bond portion provided on the emitter electrode and adjacent to a connection portion between the emitter electrode and the sense wiring; and
a second wire bond portion provided on the emitter electrode on a side opposite to the connection portion with respect to the first wire bond portion, wherein
an active cell is provided on the semiconductor substrate in a region surrounded by an end of the emitter electrode and a line portion from the first wire bond portion to the end of the emitter electrode in a straight line extending from the second wire bond portion to the end of the emitter electrode through the first wire bond portion, and
when length of the line portion is L, current density in a cross-sectional direction flowing between the connection portion and the first wire bond portion is Is, specific resistance of the emitter electrode is ρ, a number of series of diodes included in the temperature sensing unit is N, and voltage between the connection portion and the first wire bond portion is ΔV, ΔV=Is×ρ×L<0.7×N holds.

### (Appendix 6)

The semiconductor device according to Appendix 4 or 5, wherein the ΔV is 50% or less of a range between upper and lower limits of standard voltage of the temperature sensing unit.

### (Appendix 7)

The semiconductor device according to Appendix 4 or 5, wherein the ΔV is 30% or less of a range between upper and lower limits of standard voltage of the temperature sensing unit.

### (Appendix 8)

The semiconductor device according to Appendix 4 or 5, wherein the ΔV is 10% or less of a range between upper and lower limits of standard voltage of the temperature sensing unit.

### (Appendix 9)

The semiconductor device according to Appendix 4 or 5, wherein the ΔV is 1% or less of a range between upper and lower limits of standard voltage of the temperature sensing unit.

### (Appendix 10)

The semiconductor device according to any one of Appendices 1 to 9, further comprising:
an electrode pad provided on a side opposite to the sense wiring with respect to the connection portion and separated from the emitter electrode.

### (Appendix 11)

The semiconductor device according to any one of Appendices 1 to 10, further comprising:
an insulating film covering the emitter electrode and the first main surface and having an opening through which the first wire bond portion is exposed.

### (Appendix 12)

The semiconductor device according to any one of Appendices 1 to 10, further comprising an insulating film that covers the emitter electrode and the first main surface in at least a partial region other than a region between the first wire bond portion and an end of the semiconductor substrate while exposing the first wire bond portion.

### (Appendix 13)

The semiconductor device according to any one of Appendices 1 to 12, wherein
a region where the first wire bond portion is provided in the semiconductor substrate is an ineffective region.

### (Appendix 14)

The semiconductor device according to any one of Appendices 1 to 13, further comprising a wiring connected to the temperature sensing unit and overlapping at least a part of the sense wiring in plan view.

### (Appendix 15)

The semiconductor device according to any one of Appendices 1 to 14, wherein
the semiconductor substrate has a rectangular shape in plan view, and
the first wire bond portion is provided on a side of a long side of the semiconductor substrate.

While the disclosure has been shown and described in detail, the foregoing description is in all aspects illustrative and not restrictive. It is therefore understood that numerous modifications and variations can be devised.

What is claimed is:

1. A semiconductor device, comprising:
a semiconductor substrate having a first main surface;
an emitter electrode selectively provided on the first main surface;
a temperature sensing unit provided on the first main surface and adjacent to the emitter electrode further on an inner side than a terminal end of the semiconductor substrate in plan view;
a sense wiring having one end connected to the temperature sensing unit and another end connected to the emitter electrode at the terminal end of the semiconductor substrate, the sense wiring being provided along the emitter electrode; and
a first wire bond portion provided on the emitter electrode and adjacent to a connection portion between the emitter electrode and the sense wiring, wherein
the sense wiring includes:
a first sense wiring portion extending in a first direction from the inner side of the semiconductor substrate to the terminal end in plan view;
a second sense wiring portion extending at the terminal end from the first sense wiring portion to the connection portion along a second direction different from the first direction of the first sense wiring portion; and
a bent portion between the first sense wiring portion and the second sense wiring portion, and
a distance from the connection portion to the first wire bond portion is shorter than a distance from the bent portion to the connection portion.

2. A semiconductor device, comprising:
a semiconductor substrate having a first main surface;
an emitter electrode selectively provided on the first main surface;
a temperature sensing unit provided on the first main surface and adjacent to the emitter electrode further on an inner side than a terminal end of the semiconductor substrate in plan view;
a sense wiring having one end connected to the temperature sensing unit and another end connected to the emitter electrode at the terminal end of the semiconductor substrate, the sense wiring being provided along the emitter electrode; and
a first wire bond portion provided on the emitter electrode and adjacent to a connection portion between the emitter electrode and the sense wiring, wherein
the sense wiring extends in a first direction from the inner side of the semiconductor substrate to the terminal end in plan view, and
a distance from the connection portion to the first wire bond portion is shorter than a distance from the temperature sensing unit to the connection portion.

3. A semiconductor device, comprising:
a semiconductor substrate having a first main surface;
an emitter electrode selectively provided on the first main surface;
a temperature sensing unit provided on the first main surface and adjacent to the emitter electrode;
a sense wiring having one end connected to the temperature sensing unit and another end connected to the emitter electrode, the sense wiring being provided along the emitter electrode; and
a first wire bond portion provided on the emitter electrode and adjacent to a connection portion between the emitter electrode and the sense wiring, wherein
the sense wiring, the connection portion, and the emitter electrode as a whole have a U shape in plan view, and
an electrode does not exist in a portion in the U shape.

4. A semiconductor device, comprising:
a semiconductor substrate having a first main surface;
an emitter electrode selectively provided on the first main surface;
a temperature sensing unit provided on the first main surface;
a sense wiring having one end connected to the temperature sensing unit and another end connected to the emitter electrode; and
a first wire bond portion provided on the emitter electrode and adjacent to a connection portion between the emitter electrode and the sense wiring, wherein
an active cell is provided on the semiconductor substrate in a quadrangle having a line segment between the connection portion and the first wire bond portion as a diagonal line, and
when length of the diagonal line is L, current density in a cross-sectional direction flowing between the connection portion and the first wire bond portion is Is, specific resistance of the emitter electrode is ρ, a number of series of diodes included in the temperature sensing unit is N, and voltage between the connection portion and the first wire bond portion is ΔV, ΔV=Is×ρ×L<0.7×N holds.

5. A semiconductor device, comprising:
a semiconductor substrate having a first main surface;
an emitter electrode selectively provided on the first main surface;
a temperature sensing unit provided on the first main surface;
a sense wiring having one end connected to the temperature sensing unit and another end connected to the emitter electrode;
a first wire bond portion provided on the emitter electrode and adjacent to a connection portion between the emitter electrode and the sense wiring; and
a second wire bond portion provided on the emitter electrode on a side opposite to the connection portion with respect to the first wire bond portion, wherein
an active cell is provided on the semiconductor substrate in a region surrounded by an end of the emitter electrode and a line portion from the first wire bond portion to the end of the emitter electrode in a straight line extending from the second wire bond portion to the end of the emitter electrode through the first wire bond portion, and
when length of the line portion is L, current density in a cross-sectional direction flowing between the connection portion and the first wire bond portion is Is, specific resistance of the emitter electrode is ρ, a number of series of diodes included in the temperature sensing unit is N, and voltage between the connection portion and the first wire bond portion is ΔV, ΔV=Is×ρ×L<0.7×N holds.

6. The semiconductor device according to claim 4, wherein
the ΔV is 50% or less of a range between upper and lower limits of standard voltage of the temperature sensing unit.

7. The semiconductor device according to claim 4, wherein
the ΔV is 30% or less of a range between upper and lower limits of standard voltage of the temperature sensing unit.

8. The semiconductor device according to claim 4, wherein
the ΔV is 10% or less of a range between upper and lower limits of standard voltage of the temperature sensing unit.

9. The semiconductor device according to claim 4, wherein
the ΔV is 1% or less of a range between upper and lower limits of standard voltage of the temperature sensing unit.

10. The semiconductor device according to claim 1, further comprising
an electrode pad provided on a side opposite to the sense wiring with respect to the connection portion and separated from the emitter electrode.

11. The semiconductor device according to claim 1, further comprising
an insulating film covering the emitter electrode and the first main surface and having an opening through which the first wire bond portion is exposed.

12. The semiconductor device according to claim 1, further comprising an insulating film that covers the emitter electrode and the first main surface in at least a partial region other than a region between the first wire bond portion and an end of the semiconductor substrate while exposing the first wire bond portion.

13. The semiconductor device according to claim 1, wherein
a region where the first wire bond portion is provided in the semiconductor substrate is an ineffective region.

14. The semiconductor device according to claim 1, further comprising a wiring connected to the temperature sensing unit and overlapping at least a part of the sense wiring in plan view.

15. The semiconductor device according to claim 1, wherein
the semiconductor substrate has a rectangular shape in plan view, and
the first wire bond portion is provided on a side of a long side of the semiconductor substrate.
